(19) United States
(12) Patent Application Publication
(10) Pub. No.: US 2006/0088730 A1
(43) Pub. Date: Apr. 27, 2006

(54) Organic light-emitting devices with improved performance

(75) Inventors: William J. Begley, Webster, NY (US); Tukaram K. Hatwar, Penfield, NY (US); Manju Rajeswaran, Fairport, NY (US); Natasha Andrievsky, Webster, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 10/973,078

(22) Filed: Oct. 25, 2004

(51) Int. Cl. H01L 51/54; H05B 33/14

(52) U.S. Cl. 428/690; 428/917; 313/504; 313/506; 257/E51.026

(57) ABSTRACT

An OLED device comprises a light emitting layer containing a certain type of electroluminescent component having a first bandgap, a non-electroluminescent component having a second bandgap, and one or more further non-electroluminescent components having further bandgaps, wherein the components have certain bandgap relationships.

### CROSS REFERENCE TO RELATED APPLICATIONS

Reference is made to commonly assigned U.S. Ser. No. 10/334,324, filed Dec. 31, 2002 by Christopher T. Brown, et al., entitled “Efficient Electroluminescent Device”; U.S. Ser. No. 10/658,010, filed Sep. 9, 2003 by Christopher T. Brown, et al., entitled “Efficient Electroluminescent Device”; and U.S. Ser. No. 10/644,245 filed Aug. 20, 2003, by Tukaram K. Hatwar, et al., entitled “White Light-Emitting Device With Improved Doping”.

### FIELD OF THE INVENTION

This invention relates to an organic light emitting diode (OLED) electroluminescent (EL) device and more particularly comprising a light-emitting layer containing at least one electroluminescent compound (ELC) and at least two non-electroluminescent compounds (non-ELCs).

### BACKGROUND OF THE INVENTION

While organic electroluminescent (EL) devices have been known for over two decades, their performance limitations have represented a barrier to many desirable applications. In simplest form, an organic EL device is comprised of an anode for hole injection, a cathode for electron injection, and an organic medium sandwiched between these electrodes to support charge recombination that yields emission of light. These devices are also commonly referred to as organic light-emitting diodes, or OLEDs. Representative of earlier organic EL devices are Gurnee et al. U.S. Pat. No. 3,172,862, issued Mar. 9, 1965; Gurnee U.S. Pat. No. 3,173,050, issued Mar. 9, 1965; Dresner, “Double Injection Electroluminescence in Anthracene”, RCA Review, Vol. 30, pp. 322-334, 1969; and Dresner U.S. Pat. No. 3,710,167, issued Jan. 9, 1973. The organic layers in these devices, usually composed of a polycyclic aromatic hydrocarbon, were very thick (much greater than 1 μm). Consequently, operating voltages were very high, often >100V.

More recent organic EL devices include an organic EL element consisting of extremely thin layers (e.g. <1.0 μm) between the anode and the cathode. Herein, the organic EL element encompasses the layers between the anode and cathode electrodes. Reducing the thickness lowered the resistance of the organic layer and has enabled devices that operate at much lower voltage. In a basic two-layer EL device structure, described first in U.S. Pat. No. 4,356,429, one organic layer of the EL element adjacent to the anode is specifically chosen to transport holes, therefore, it is referred to as the hole-transporting layer, and the other organic layer is specifically chosen to transport electrons, referred to as the electron-transporting layer. The interface between the two layers provides an efficient site for the recombination of the injected hole/electron pair and the resultant electroluminescence.

There have also been proposed three-layer organic EL devices that contain an organic light-emitting layer (LEL) between the hole- transporting layer and electron-transporting layer, such as that disclosed by Tang et al [J. Applied Physics, Vol. 65, Pages 3610-3616, 1989]. The light-emitting layer commonly consists of a non-electroluminescent compound (non-ELC) doped with a guest material—an electroluminescent compound (ELC), which results in an efficiency improvement and allows color tuning.

Since these early inventions, further improvements in device materials have resulted in improved performance in attributes such as color, stability, luminance efficiency and manufacturability, e.g., as disclosed in U.S. Pat. No. 5,061,569, U.S. Pat. No. 5,409,783, U.S. Pat. No. 5,554,450, U.S. Pat. No. 5,593,788, U.S. Pat. No. 5,683,823, U.S. Pat. No. 5,908,581, U.S. Pat. No. 5,928,802, U.S. Pat. No. 6,020,078, and U.S. Pat. No. 6,208,077, amongst others.

Notwithstanding these developments, there are continuing needs for organic EL device components, such as electroluminescent and non-electroluminescent compounds or portions of a polymer, that will provide high luminance efficiencies combined with high color purity, long lifetimes and low operating voltages.

A useful class of electroluminescent compounds is derived from the DCM class of compounds (4-dicyanomethylene-4H-pyrans) and disclosed in EP-A-1,162,674; US-A-2002/0,127,427 and U.S. Pat. No. 5,908,581. A broad emission envelope and a high luminance quantum yield characterize these materials. However, the operational stability, operational drive voltage, color purity and EL efficiency of these materials in an OLED is insufficient for a broad range of OLED applications.

Another useful class of electroluminescent compounds is the periflanthene class of materials as disclosed in EP-A-1,148,109; EP-A-1,235,466; EP-A-1,182,244; U.S. Pat. No. 6,004,685; Bard et al [J. Organic Chemistry, Vol. 62, Pages 530-537, 1997; J. American Chemical Society, Vol. 118, Pages 2374-2379, 1996]. These materials are characterized by a “perylene-type” emission in the red region of the visible spectrum.

Young et. al., in U.S. Pat. No. 6,720,090 teaches an organic light emitting device with at least one dopant and a host material comprising a mixture of at least two components. The first host component can include a polycyclic hydrocarbon (PAH) of the tetracene type.

Antoniadis et. al., in U.S. Pat. No. 6,004,685 teaches the use of dibenzotetraphenylperiflanthene as a dopant in a first electron transport material in the electroluminescent layer.

Ara et. al., in U.S. Pat. No. 6,613,454 describes-an organic EL device with at least one of the organic layers containing at least one organic compound selected from a given list of compounds. One class of organic compounds in U.S. Pat. No. 6,613,454 is naphthacene-based and includes 5,6,11,12-tetra-(2′-naphthalenyl)naphthacene (NR). Again there is no teaching of naphthacene-based compounds having the same single substituent at both ends of the naphthacene nucleus and on two of the phenyl groups of the naphthacene.

Terazono et. al., in JP11273861A2 describes an electroluminescent element comprising an emissive layer having 8-oxyquinoline-based complex as an organic emissive material wherein one of the possible compounds in the element is rubrene-based, and contained in the emissive layer in a concentration of 0.01 mole-% to 30 mole-%. They teach a combination of 8-oxyquinoline-based complex together with 9,10-diphenylanthracene based and rubrene-based compounds. There is no teaching of naphthacene-based compounds having the same single substituent at both ends of the naphthacene nucleus and on two of the phenyl groups.

However, these devices do not have the desired EL characteristics in terms of luminance, and stability of the components in the devices.

It is a problem to be solved to provide an OLED device having a light-emitting layer (LEL) that exhibits improved luminance and stability characteristics.

### SUMMARY OF THE INVENTION

The invention provides an OLED device comprising a light emitting layer containing an electroluminescent component having a first bandgap, a non-electroluminescent component having a second bandgap, and one or more further non-electroluminescent components having further bandgaps, wherein:

i) the second bandgap is equal to or greater than the first bandgap but is not more than 2.7 eV;

ii) each of the one or more further bandgap is greater than the first and second bandgaps;

iii) the non-electroluminescent component with the second bandgap is present in an amount of 0.1 to 99.8 vol. percent of the total material in the light emitting layer;

iv) the one or more non-electroluminescent components with further bandgaps are present in a combined amount of 0.1 to 99.8 vol percent of the total material in the light emitting layer;

v) the electroluminescent component is present in an amount of 0.1 to 5 vol. percent of the total material in the light emitting layer; and

vi) the non-electroluminescent component with the second bandgap is represented by formula (Ia); 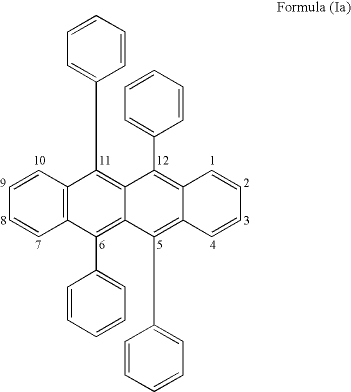
wherein:

a) any hydrogen on the phenyl rings in the 6- and 12-positions may be substituted;

b) there are identical substituent groups at the 2- and 8-positions; and

c) the phenyl rings in the 5- and 11-positions contain only para-substituents identical to the substituent groups in paragraph b).

The invention also provides a display including such a device and a method of emitting light or imaging using such a device.

Such a device exhibits improved luminance and stability characteristics.

### BRIEF DESCRIPTION OF THE DRAWINGS

FIG. 1 shows a cross-section of a typical OLED device wherein the light-emitting layer useful in the present invention is employed.

### DETAILED DESCRIPTION OF THE INVENTION

The invention is generally as described above.

An OLED device of the invention is a multilayer electroluminescent device comprising a cathode, an anode, and a light-emitting layer (LEL) comprising at least two non-electroluminescent components (non-ELCs) and at least one electroluminescent component (ELC), such as a periflanthene or a pyran and may include other layers such as charge-injecting layers, charge-transporting layers, and blocking layers.

As used herein, the term “component” is used interchangeably with “compound” and both are understood to include not only a separate compound but also the corresponding portion of a polymeric compound. The term electroluminescent component or compound means a component which, in the combination, electroluminesces in the range of 400-700 nm.

The term non-electroluminescent component or compound means a component for which, in the combination, does not significantly electroluminesce in the range of 400-700 nm.

The term periflanthene is a trivial name describing the central diindenoperylene structure of dibenzo {[f,f′]-4,4′,7,7′-tetraphenyl}-diindeno[1,2,3-cd:1′,2′,3′-lm]perylene. The diindenoperylene core is composed of two indene fusions with the 1,2,3-positions of an indene and the cd and lm faces of a perylene. [The Naming and Indexing of Chemical Substances for Chemical Abstract—A Reprint of Index IV (Chemical Substance Index Names) from the Chemical Abstracts—1992 Index Guide; American Chemical Society: Columbus, Ohio, 1992; paragraph 135,148 and 150. The first description of a periflanthene was in 1937 (Braun, J.; Manz, G., Ber. 1937, 70, 1603). In this case indene can also include analogous materials wherein the benzo-group of indene can be a ring of 5, 6, or 7 atoms comprising carbon or heteroatoms such as nitrogen, sulfur or oxygen.

The compound designated as Inv-1 and related “diindenoperylene” compounds Inv-2 through Inv-11, can be prepared via standard accepted protocols involving aluminum chloride (Braun, J.; Manzi G., Ber. 1937, 70, 1603), cobalt(III)fluoride (Debad, J. D.; Morris, J. C.; Lynch, V.; Magnus, P.; Bard, A. J. Am. Chem. Soc. 1996, 118, 2374-2379) and thallium trifluoracetate (Feiler, L.; Langhals, H.; Polborn, K. Liebigs Ann. 1995, 1229-1244).

Suitably, the light-emitting layer of the device comprises at least two non-electroluminescent components and at least one electroluminescent component where the electroluminescent component is present in an amount of 0.1 to 5% of the total material of the light emitting layer, more typically from 0.1-2.0% of the total material of the light emitting layer. This electroluminescent component has a first bandgap. The non-electroluminescent components function as an initial “energy capture agent” that transfers that energy to the electroluminescent component or guest material as the primary light emitter. The non-electroluminescent component comprises at least two non-electroluminescent components with second and further bandgaps, respectively. The non-electroluminescent component with a second bandgap is present in the light emitting layer in an amount of 0.1 to 99.8% of the total material and the non-electroluminescent component with a further bandgap is also present in the light emitting layer in an amount of 0.1 to 99.8% of the total layer. The total amount of non-electroluminescent components amounts to at most 99.9% of the material of the light-emitting layer, with the electroluminescent component accounting for the remainder. Desirably, the amount of the non-electroluminescent component with the second bandgap present in the light emitting layer is in an amount of 5 to 95% of the total material of the light-emitting layer with more typically, 10 to 75% being employed. The remainder of the material is made up of the non-electroluminescent components or compounds with the further bandgap or bandgaps and the electroluminescent component or components.

One useful embodiment of the invention is one where the non-electroluminescent component with the second bandgap is represented by Formula (Ib): 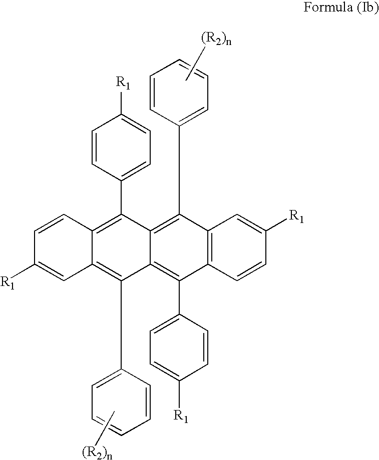
wherein

R₁ and R₂ are substituent groups;

n is 1-5;

provided that the R₁ groups are the same; and

provided further, that the R₂ groups, their location and n value on one ring are the same as those on the second ring.

A particularly useful embodiment of the non-electroluminescent component of Formula (Ib) is one in which R₁ is represented by the formula;

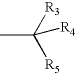

wherein each of R₃, R₄ and R₅ is hydrogen or an independently selected substituent or R₃, R₄ and R₅ taken together can form a mono- or multi-cyclic ring system. Particularly useful R₃, R₄ and R₅ groups are alkyl groups. When R₃, R₄ and R₅ are alkyl groups, specifically useful groups are methyl groups.

Embodiments of the electroluminescent components useful in the invention provide an emitted light having a red hue. Substituents are selected to provide embodiments that exhibit a reduced loss of initial luminance compared to the device containing no diindenoperylene of claim 1.

Electroluminescent components useful in the invention are suitably represented by Formula (II): 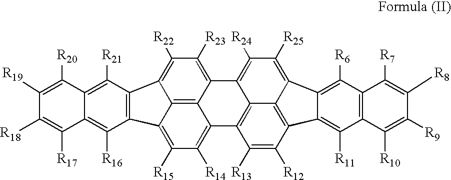
wherein:

R₆, R₇, R₈, R₉, R₁₀, R₁₁, R₁₂, R₁₃, R₁₄, R₁₅, R₁₆, R₁₇, R₁₈, R₁₉, R₂₀, R₂₁, R₂₂, R₂₃, R₂₄ and R₂₅ are independently selected as hydrogen or substituents;

provided that any of the R₆ through R₂₅ substituents may join to form further fused rings.

A useful and convenient embodiment is where R₆, R₁₁, R₁₆, and R₂₁, are all phenyl and R₇, R₈, R₉, R₁₀, R₁₂, R₁₃, R₁₄, R₁₅, R₁₇, R₁₈, R₁₉, R₂₀, R₂₂, R₂₃, R₂₄ and R₂₅ are all hydrogen. A related embodiment is when there are no phenyl groups. Another desirable embodiment is where R₆, R₇, R₈, R₉, R₁₀, R₁₁, R₁₂, R₁₃, R₁₄, R₁₅, R₁₆, R₁₇, R₁₈, R₁₉, R₂₀, R₂₁, R₂₂, R₂₃, R₂₄ and R₂₅ are selected independently from the group consisting of hydrogen, alkyl and aryl.

The emission wavelength of these components may be adjusted to some extent by appropriate substitution around the central perylene core.

Further electroluminescent components useful in the invention are pyran derivatives suitably represented by Formula (III): 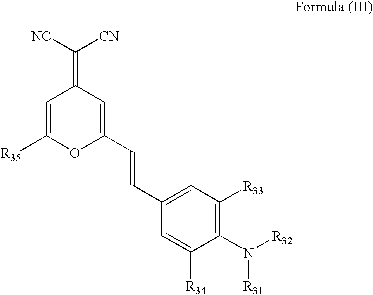
wherein:

R₃₁, R₃₂, R₃₃, R₃₄, and R₃₅ are independently selected as hydrogen or substituents;

provided that any of the indicated substituents may join to form further fused rings.

A useful and convenient embodiment is where R₃₁, R₃₂, R₃₃, R₃₄, and R₃₅ are selected independently from the group consisting of hydrogen, alkyl and aryl groups.

The electroluminescent component is usually doped into a non-electroluminescent component, which represents the light-emitting layer between the hole-transporting and electron-transporting layers. The non-electroluminescent component is chosen such that there is efficient formation of an excited state on the electroluminescent component thereby affording a bright, highly efficient, stable EL device.

Non-electroluminescent components with further bandgap(s) useful in the invention are any of those known in the art that meet the band gap requirements of the invention and are suitably represented by Formula (IV): 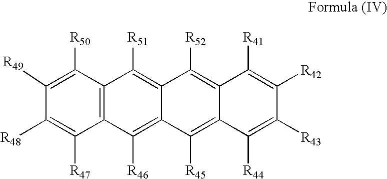
wherein:

R₄₁, R₄₂, R₄₃, R₄₄, R₄₅, R₄₆, R₄₇, R₄₈, R₄₉, R₅₀, R₅₁, and R₅₂ are independently selected as hydrogen or substituents;

provided that any of the indicated substituents may join to form further fused rings.

A useful and convenient embodiment is where at least one of R₄₁, R₄₂, R₄₃, R₄₄, R₄₅, R₄₆, R₄₇, R₄₈, R₄₉, R₅₀, R₅₁, and R₅₂ are independently selected from the group consisting of halide, alkyl, aryl, alkoxy and aryloxy groups.

The benefit imparted by the electroluminescent component does not appear to be non-electroluminescent component specific. Desirable non-electroluminescent compound(s) with the further bandgap(s) include those based on chelated oxinoids, benzazoles, anthracenes, tetracenes or tetrarylbenzidines although they are not limited to these five classes of non-electroluminescent compounds. Particular examples of non-electroluminescent compounds with the further bandgap(s) are tris(8-quinolinolato)aluminum (III) (AlQ₃, Inv-26); 2,2′,2″-(1,3,5-benzenetriyl)tris[1-phenyl-1H-benzimidazole] (TPBI); 2-tert-butyl-9,10-di-(2-naphthyl)anthracene (TBADN, Inv-22); 5,6,11,12-tetraphenylnaphthacene (Rubrene, Inv-19); N,N′-di-1-naphthalenyl-N,N′-diphenyl-4,4′-diaminobiphenyl (NPB, Inv-24); 5,12-bis[2-(5-methylbenzothiazolyl)phenyl]-6,11-diphenylnaphthacene (DBZR, Inv-21); 5,12-bis[4-tert-butylphenyl]naphthacene (tBDPN, Inv-23), 5,6,11,12-tetra-2-naphthalenylnaphthacene (NR, Inv-20), 9,10-bis(2-naphthyl)-2-phenylanthracene (Inv-25), and 9-(2-naphthyl)-10-(4-phenyl)phenylanthracene (Inv-27).

The EL device of the invention is useful in any device where stable light emission is desired such as a lamp or a component in a static or motion imaging device, such as a television, cell phone, DVD player, or computer monitor.

Examples of electroluminescent compounds with a first bandgap useful in the invention are diindeno[1,2,3-cd]perylene, illustrated in the formulae Inv-1 through Inv-11, and pyran, illustrated in formulae Inv-12 through Inv-18. Examples of non-electroluminescent compounds with a second bandgap useful in the invention are illustrated in formulae Inv-29 through Inv-68. Examples of non-electroluminescent compounds useful in the invention with a further bandgap are naphthacene, indeno[1,2,3-cd]perylene, chelated oxinoid, anthracenyl and N,N′,N,N′-tetraarylbenzidine and are illustrated in Inv-19 through Inv-28.

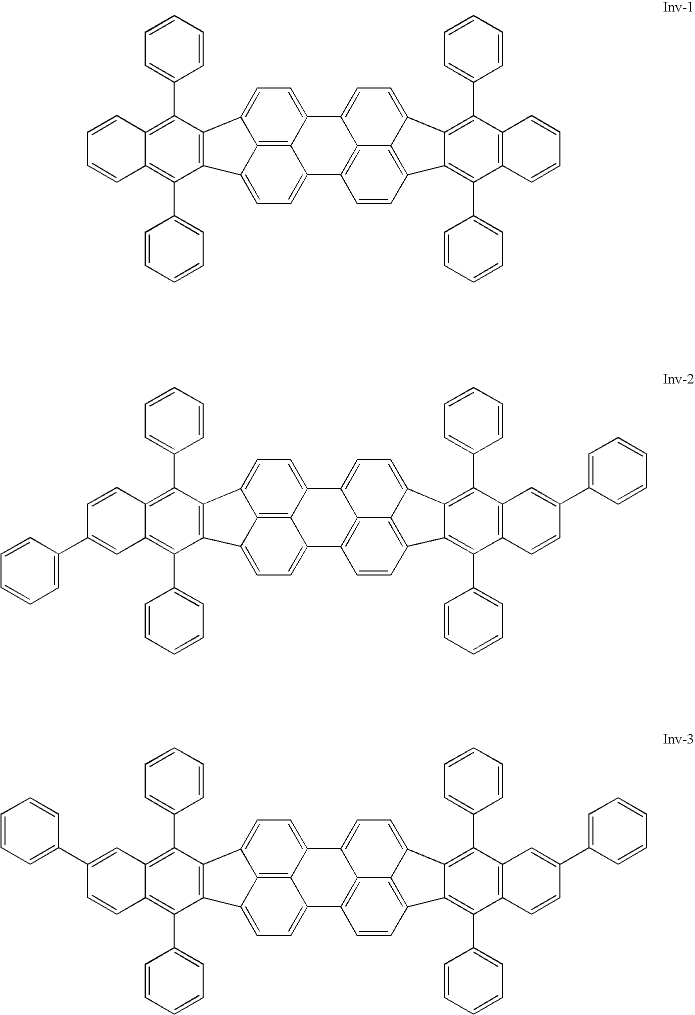

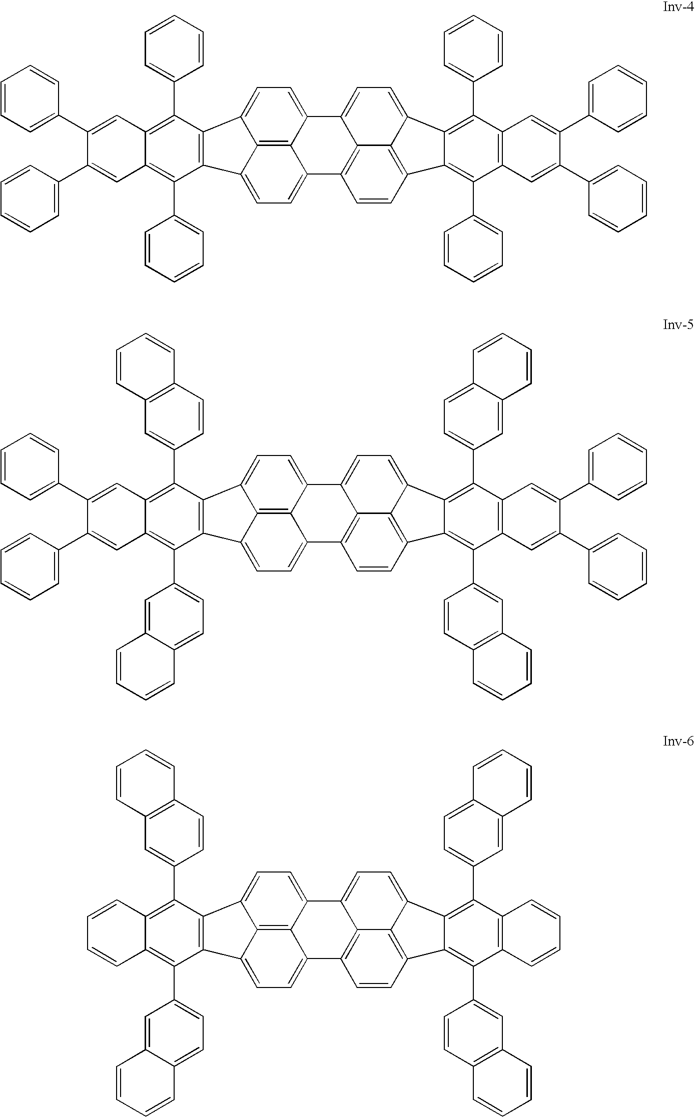

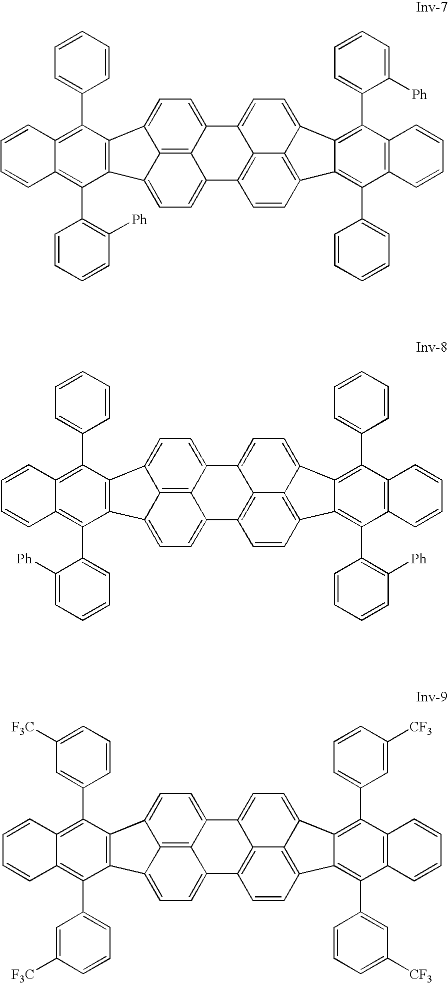

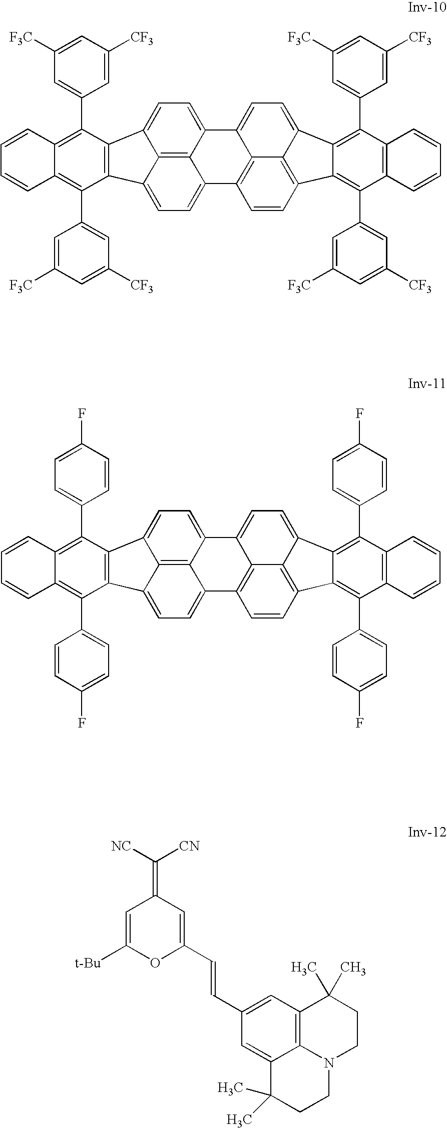

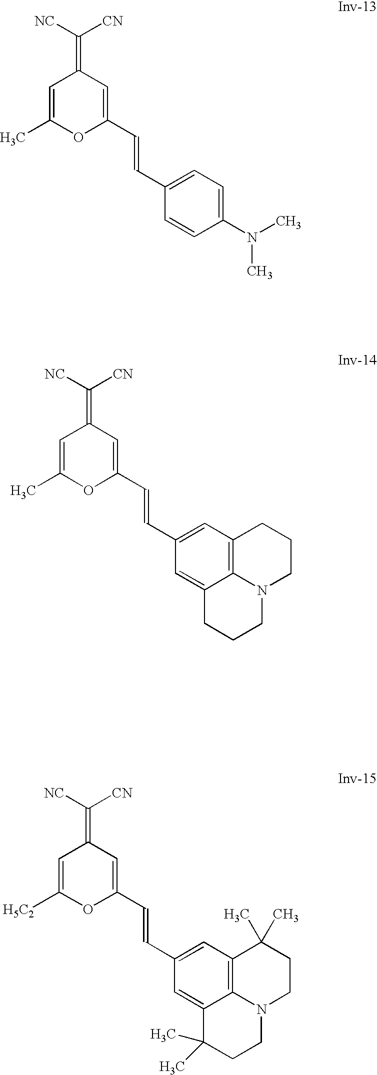

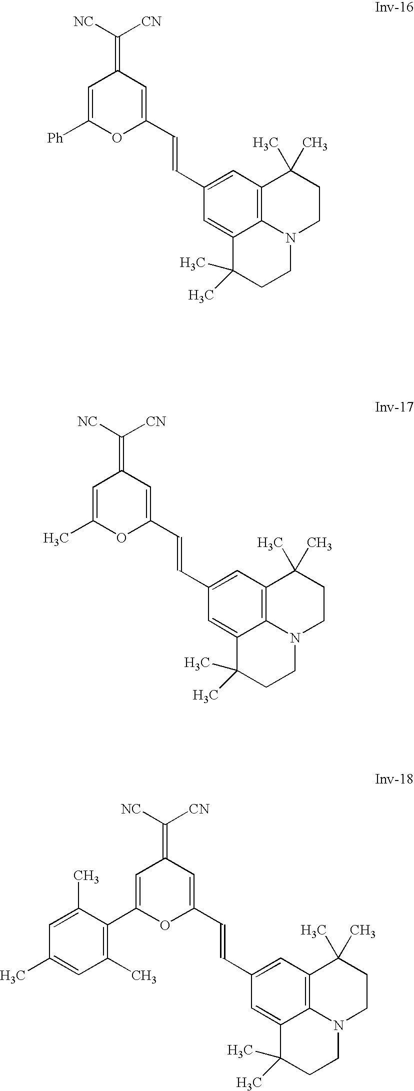

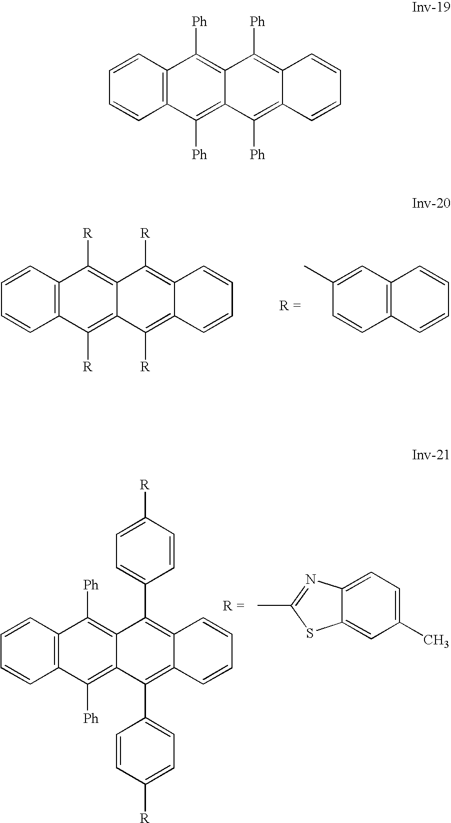

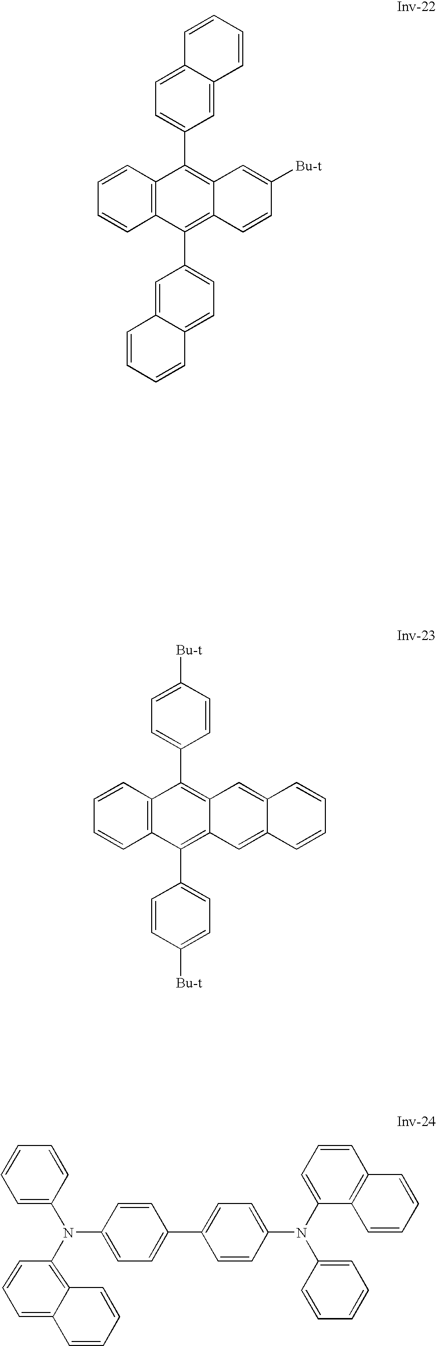

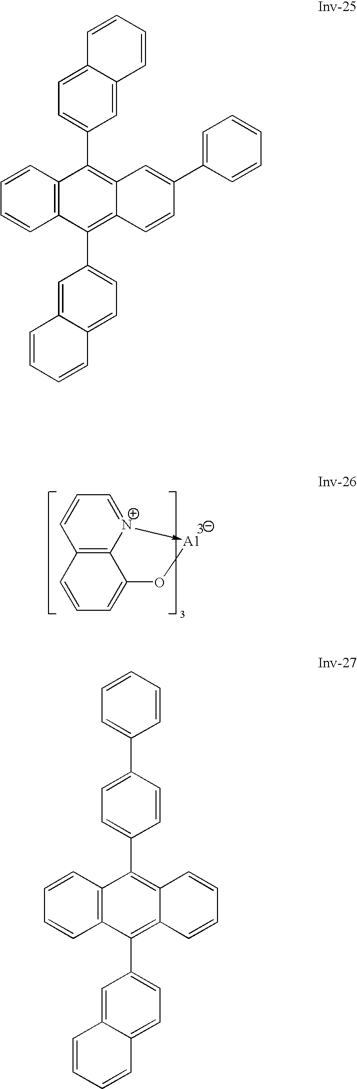

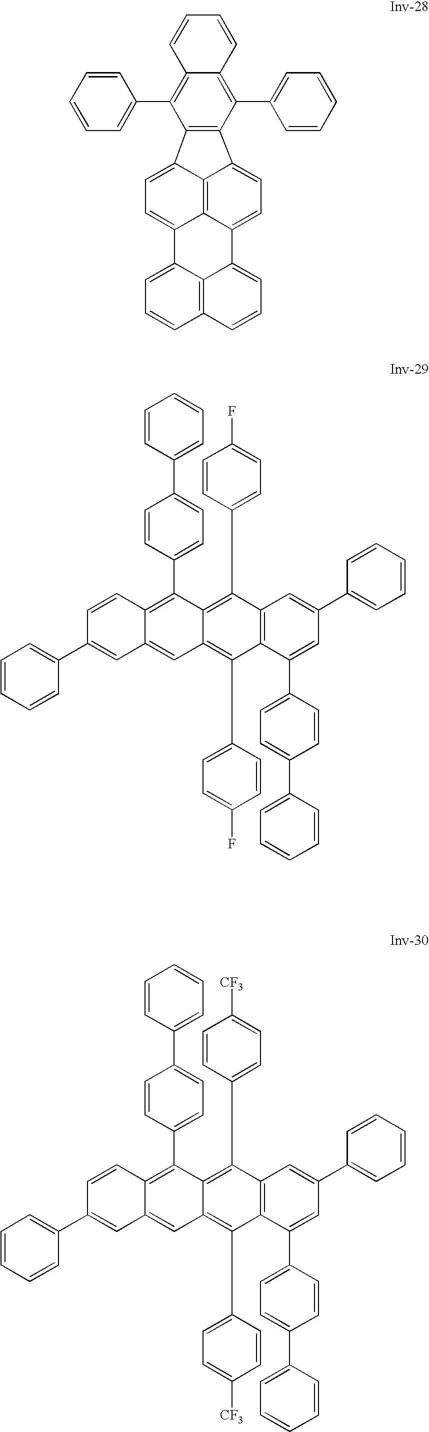

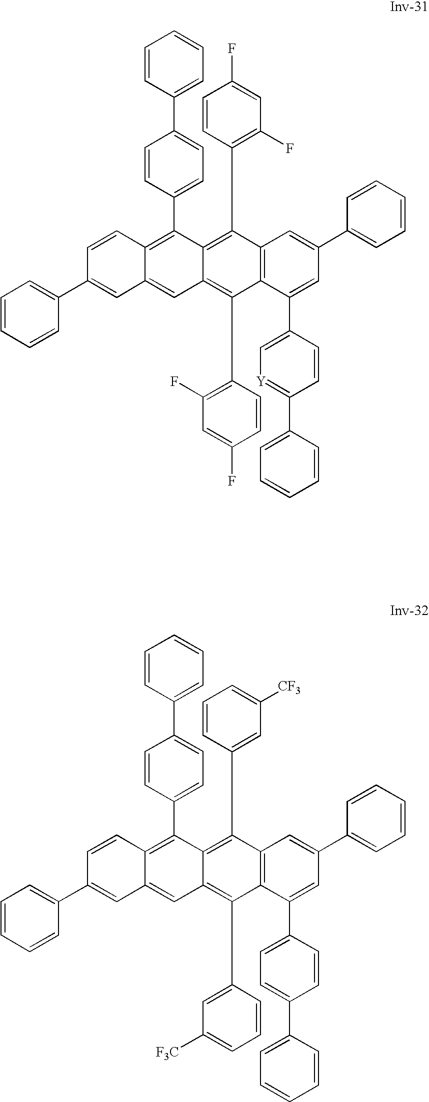

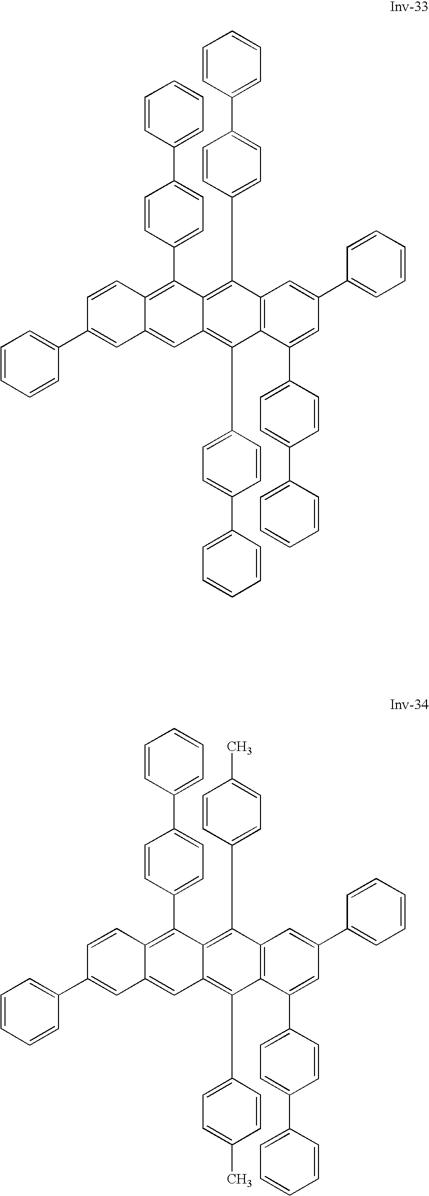

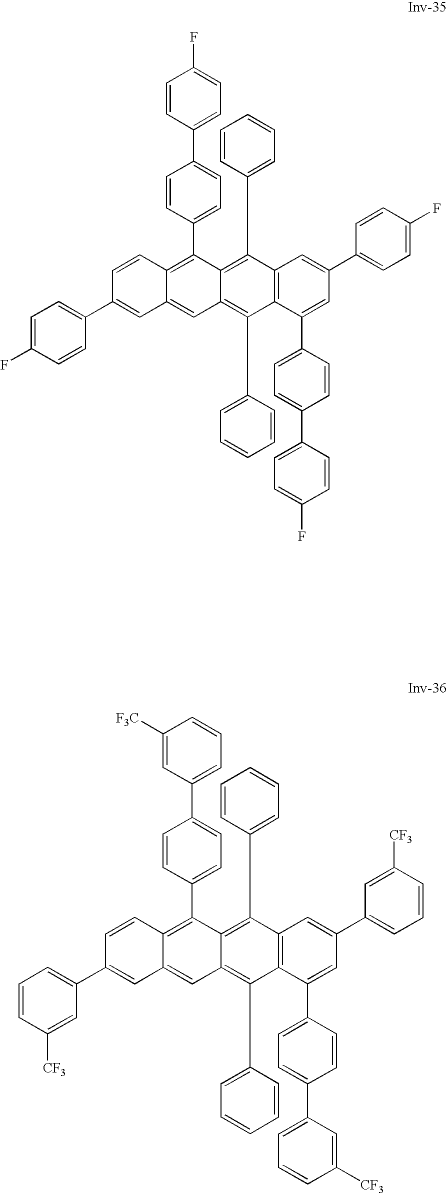

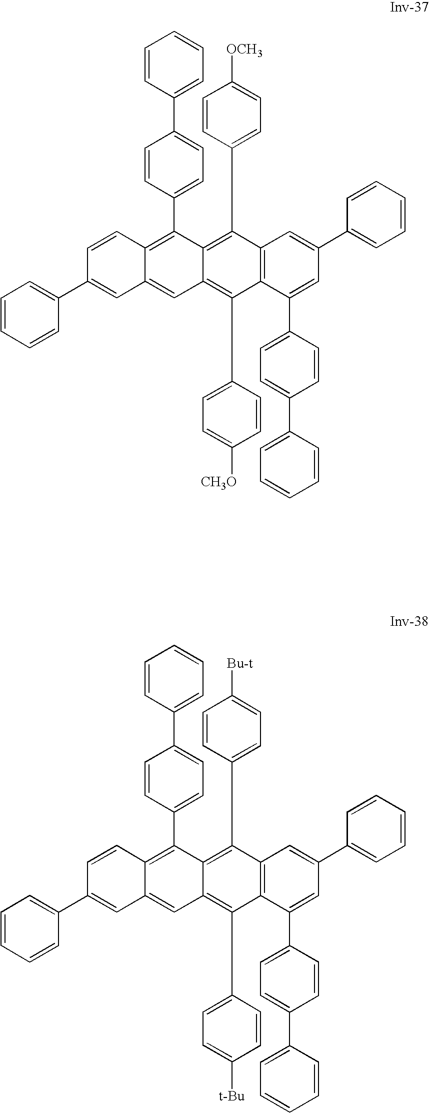

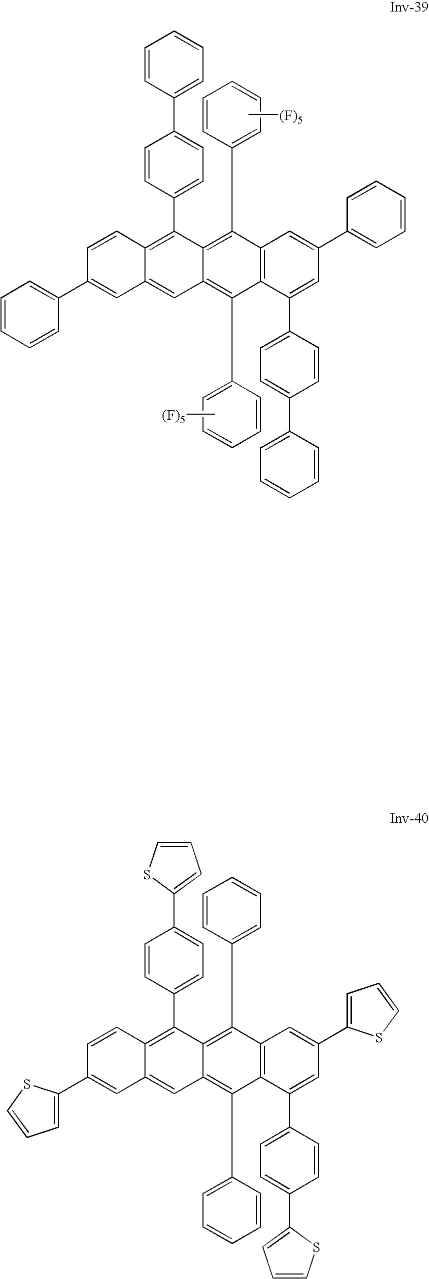

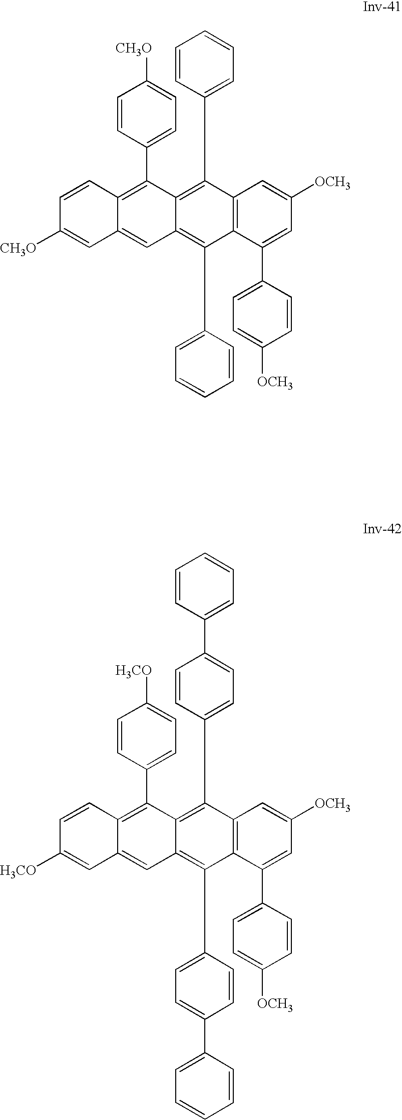

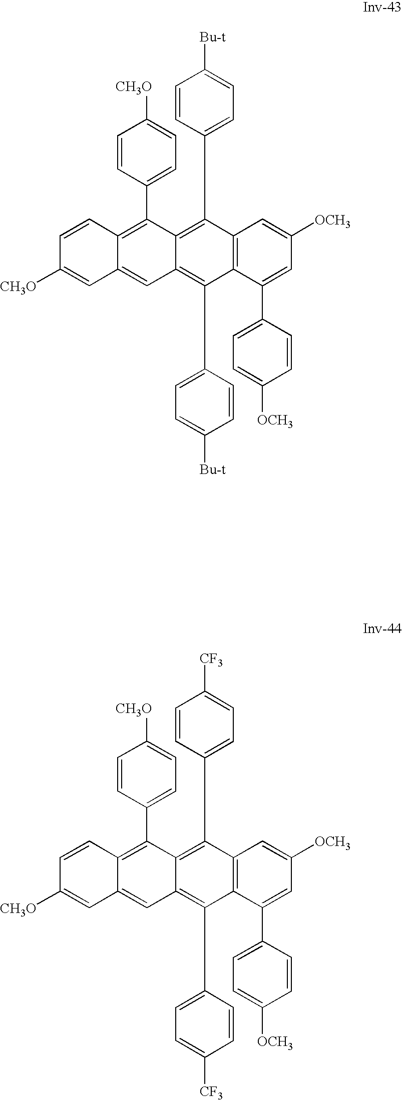

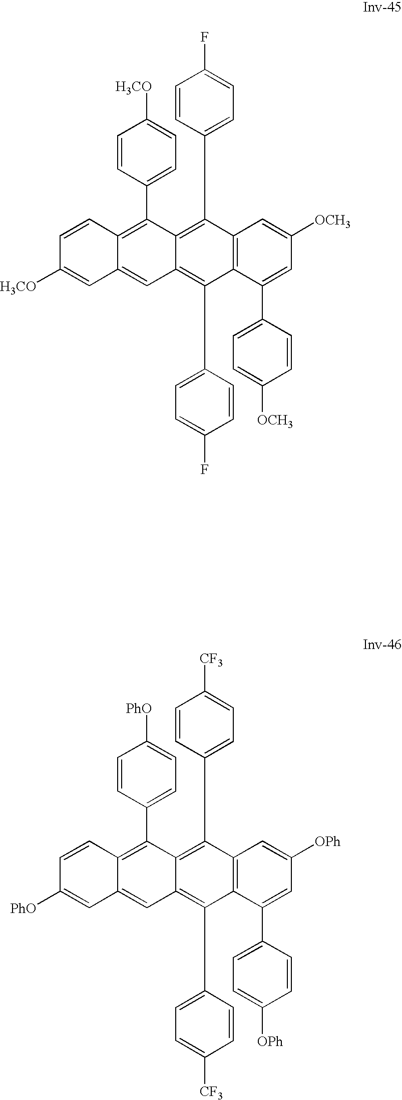

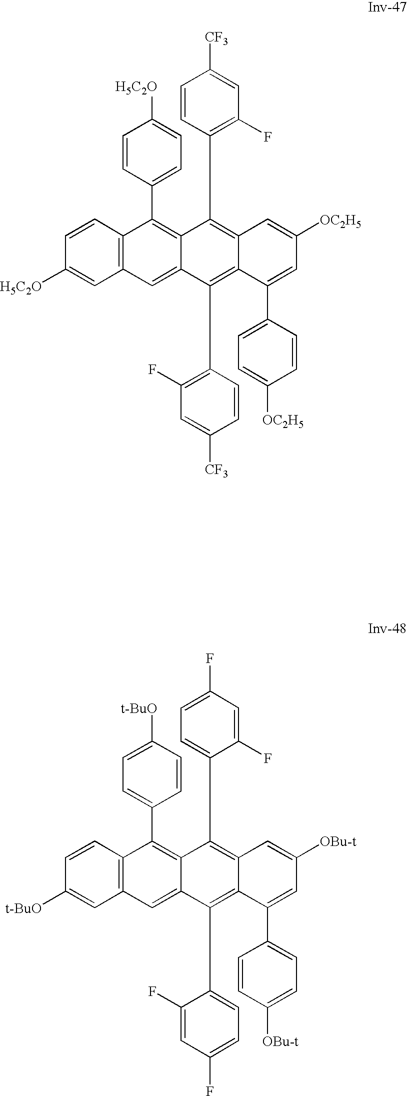

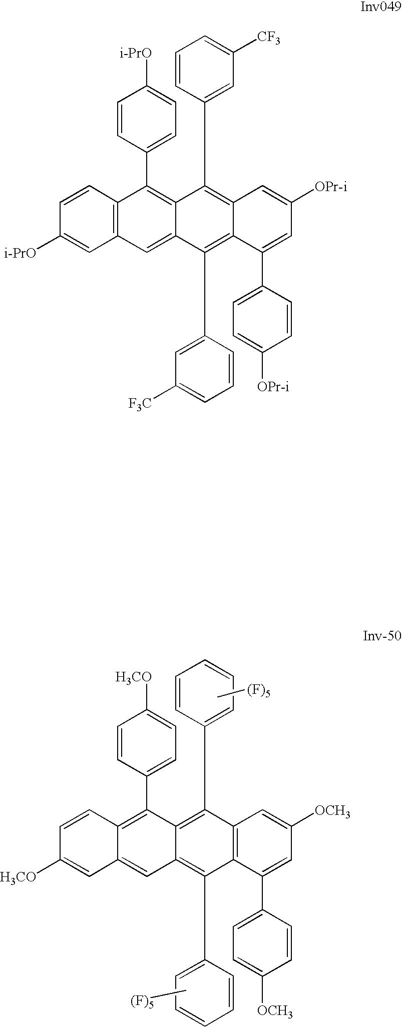

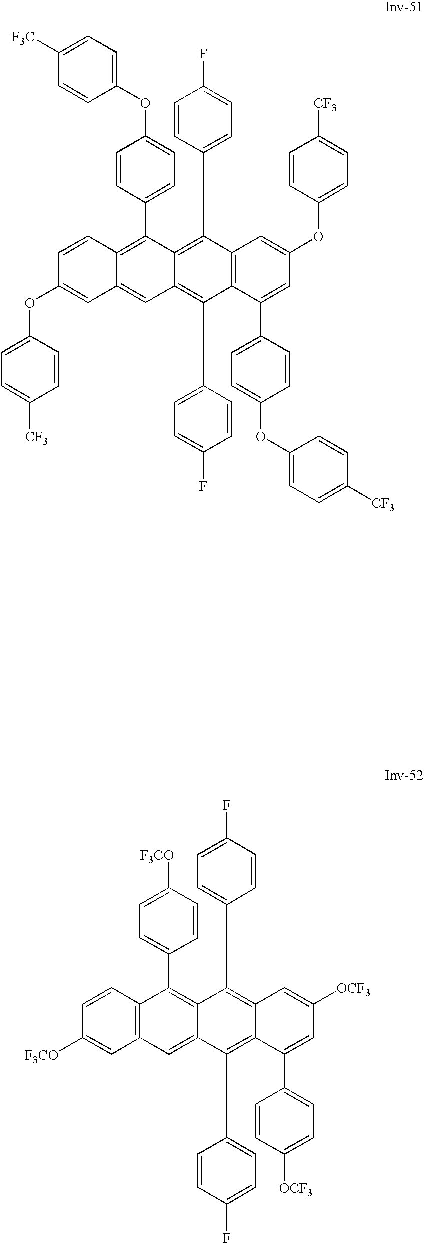

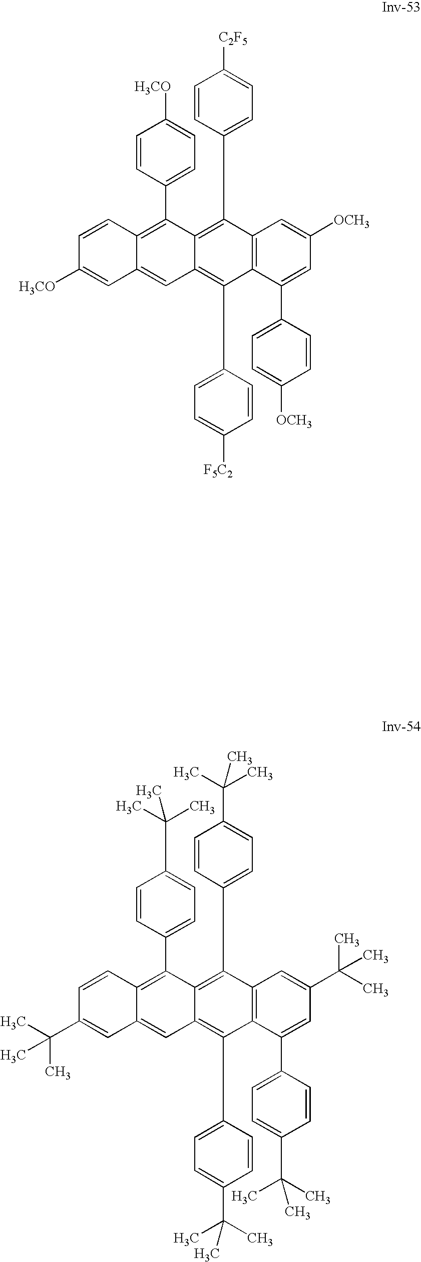

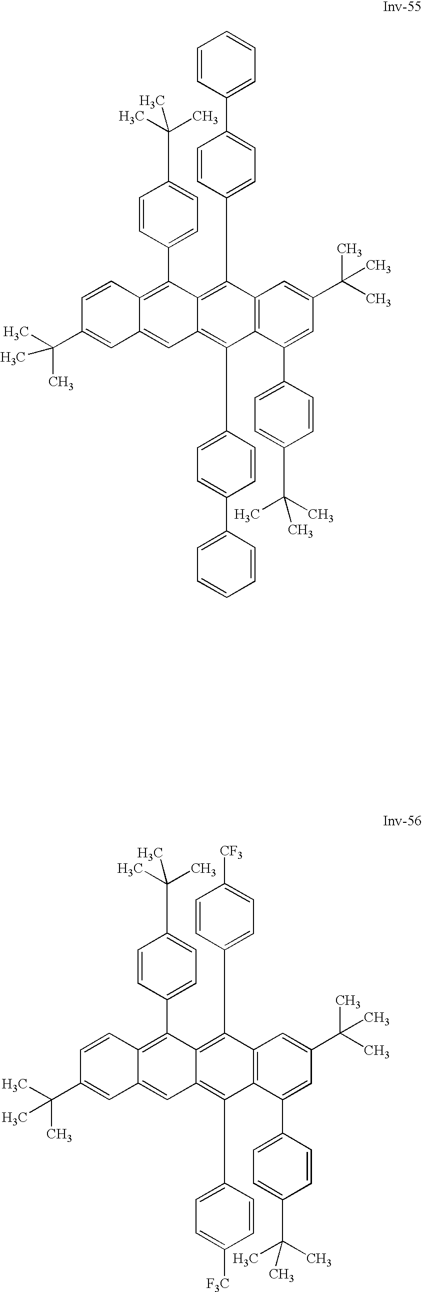

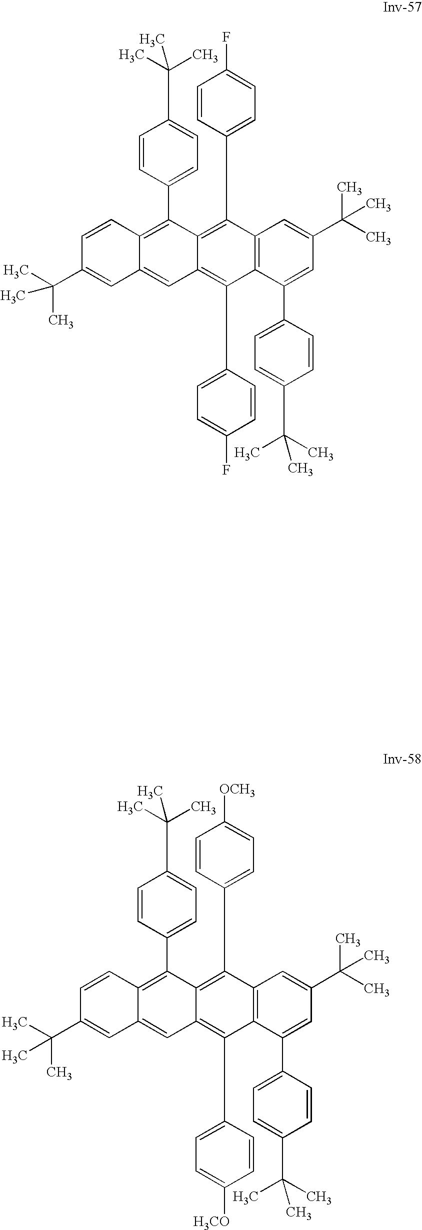

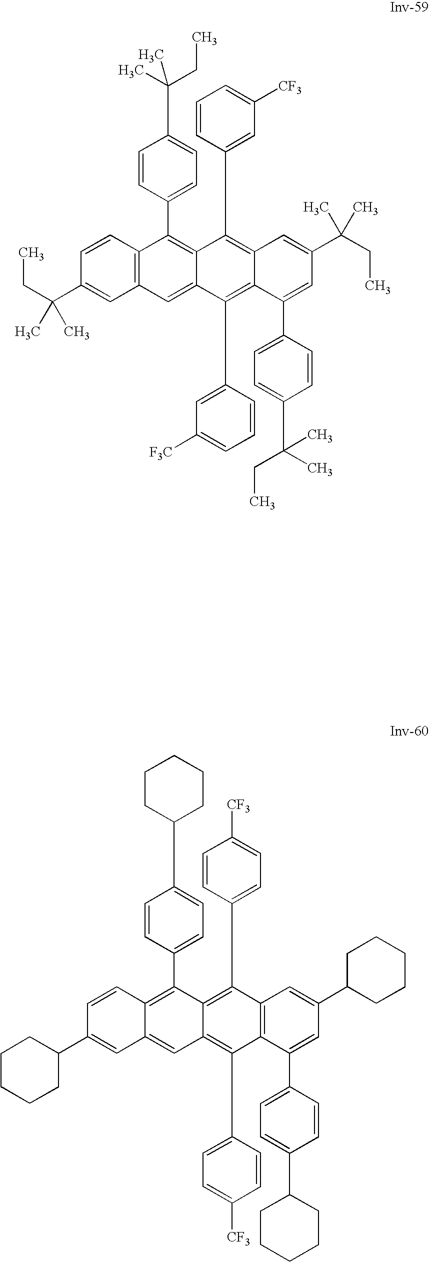

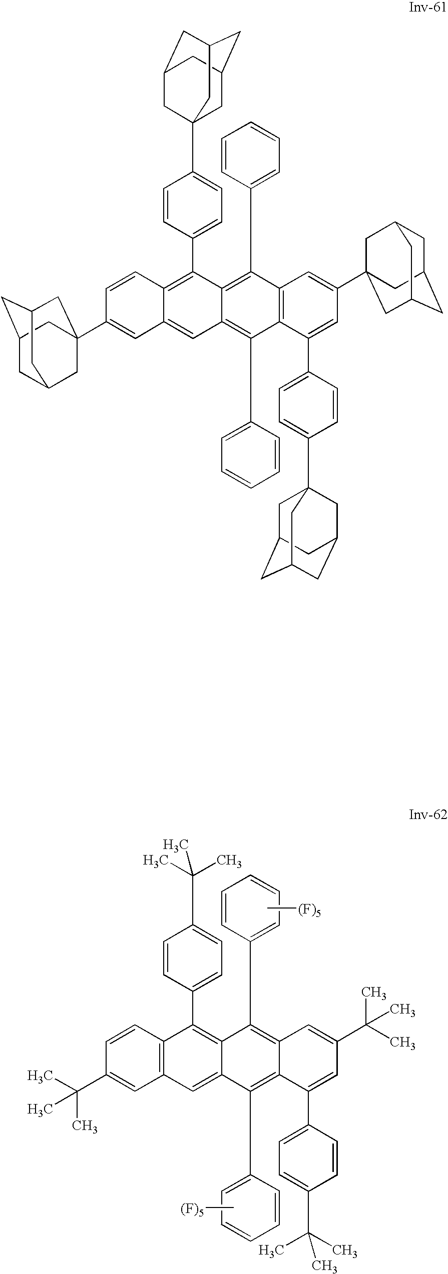

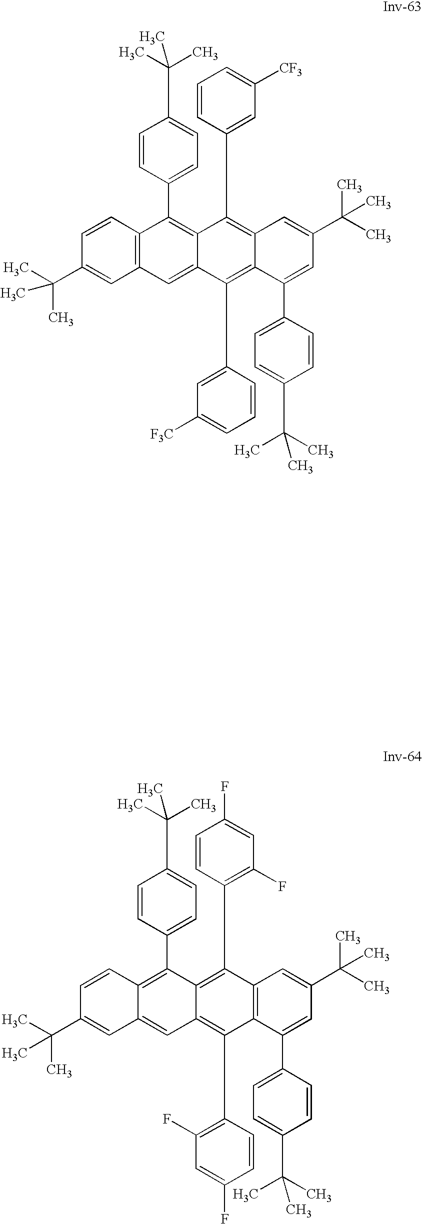

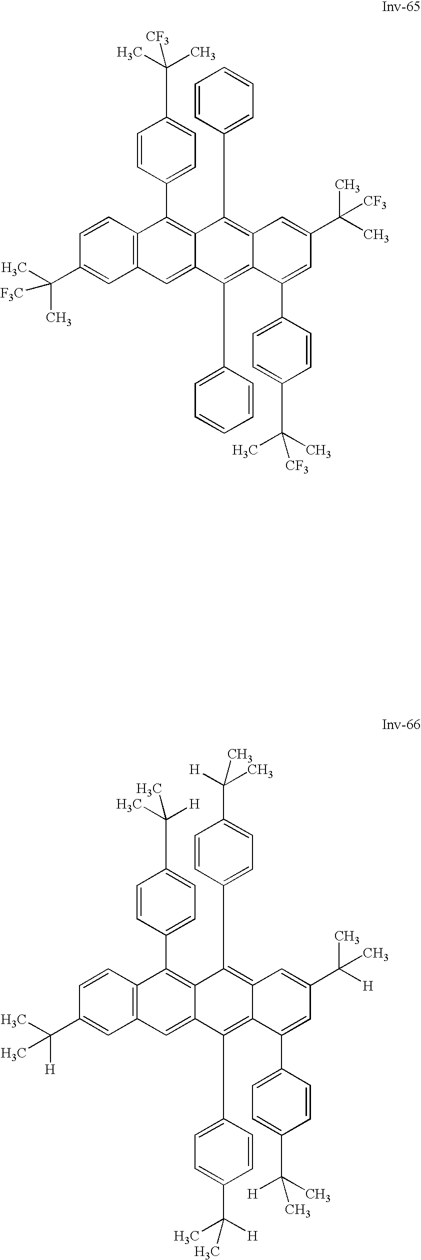

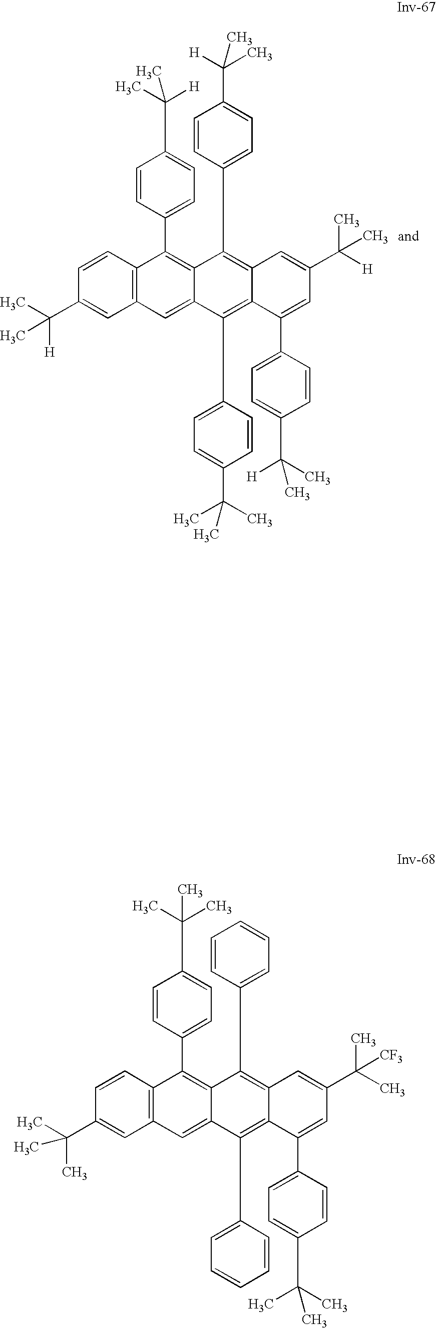

In one embodiment of the invention, the component with the second bandgap comprises 5 to 95% of the layer and in another embodiment the component with the second bandgap comprises 10 to 75% of the layer. In a useful embodiment of the invention, the component with the second bandgap comprises 5 to 95% of the layer and the electroluminescent component is a periflanthene or a pyran. In yet another useful embodiment of the invention, the component with the second bandgap comprises 10 to 75% of the layer and the electroluminescent component is a periflanthene or a pyran. The electroluminescent compound, but specifically the periflanthene or a pyran materials, can be present in the range of 0.1 to 5% of the total material in the red light emitting layer, but is typically in the range of 0.3 to 1.5%.

In another embodiment, the component with the second bandgap comprises 5 to 95% of the layer and the components with the further bandgaps are selected from a specified listing of tris(8-quinolinolato)aluminum (III) (Alq₃); 2,2′,2″-(1,3,5-benzenetriyl)tris[1-phenyl-1H-benzimidazole] (TPBI); 2-tert-butyl-9,10-bis(2-naphthyl)anthracene (TBADN); 5,6,11,12-tetraphenylnaphthacene (rubrene); N,N′-di-(1-naphthalenyl)-N,N′-diphenyl-4,4′-diamino(1,1′-biphenyl) (NPB); 4,4′-Bis[N-(1-naphthyl)-N-(2-naphthyl)amino]biphenyl(TNB); 4,4′-Bis[N-(1-naphthyl)-N-(2-naphthyl)amino]biphenyl(TNB); 5,12-bis[2-(5-methylbenzothiazolyl)phenyl]-6,11-diphenylnaphthacene (DBZR); 5,12-bis(4-tert-butylphenyl)naphthacene (tBDPN); 5,6,11,12-tetra-(2′-naphthalenyl)naphthacene (NR); 9,10-bis(2-naphthyl)-2-phenylanthracene; and 9-(2-naphthyl)-10-(4-phenyl)phenylanthracene; and in a still further embodiment there are present at least two components with a further bandgap comprising at least one selected from tris(8-quinolinolato)aluminum (III) (Alq₃); 2,2′,2″-(1,3,5-benzenetriyl)tris[1-phenyl-1H-benzimidazole] (TPBI); 2-tert-butyl-9,10-bis(2-naphthyl)anthracene (TBADN); 5,6,11,12-tetraphenylnaphthacene (rubrene); N,N′-di-(1-naphthalenyl)-N,N′-diphenyl-4, 4′-diamino(1,1′-biphenyl) (NPB); 4,4′-Bis[N-(1-naphthyl)-N-(2-naphthyl)amino]biphenyl(TNB); 5,12-bis[2-(5-methylbenzothiazolyl)phenyl]-6,11-diphenylnaphthacene (DBZR); 5,12-bis(4-tert-butylphenyl)naphthacene (tBDPN); 5,6,11,12-tetra-(2′-naphthalenyl)naphthacene (NR); 9,10-bis(2-naphthyl)-2-phenylanthracene; and 9-(2-naphthyl)-10-(4-phenyl)phenylanthracene.

In an additional embodiment, the component with the second bandgap comprises 10 to 75% of the layer and the components with the further bandgaps are selected from a specified listing of tris(8-quinolinolato)aluminum (III) (Alq₃); 2,2′,2″-(1,3,5-benzenetriyl)tris[1-phenyl-1H -benzimidazole] (TPBI); 2-tert-butyl-9,10-bis(2-naphthyl)anthracene (TBADN)-5,6,11,12-tetraphenylnaphthacene (rubrene); N,N′-di-(1-naphthalenyl)-N,N′-diphenyl-4, 4′-diamino(1,1′-biphenyl) (NPB); 4,4′-Bis[N-(1-naphthyl)-N-(2-naphthyl)amino]biphenyl(TNB); 5,12-bis[2-(5-methylbenzothiazolyl)phenyl]-6,11-diphenylnaphthacene (DBZR); 5,12-bis(4-tert-butylphenyl)naphthacene (tBDPN); 5,6,11,12-tetra-(2′-naphthalenyl)naphthacene (NR); 9,10-bis(2-naphthyl)-2-phenylanthracene; and 9-(2-naphthyl)-10-(4-phenyl)phenylanthracene; and in a still further embodiment there are present at least two components with a further bandgap comprising at least one selected from tris(8-quinolinolato)aluminum (III) (Alq₃); 2,2′,2″-(1,3,5-benzenetriyl)tris[1-phenyl-1H-benzimidazole] (TPBI); 2-tert-butyl-9,10-bis(2-naphthyl)anthracene (TBADN); 5,6,11,12-tetraphenylnaphthacene (rubrene); N,N′-di-(1-naphthalenyl)-N,N′-diphenyl-4, 4′-diamino(1,1′-biphenyl) (NPB); 4,4′-Bis[N-(1-naphthyl)-N-(2-naphthyl)amino]biphenyl(TNB); 5,12-bis[2-(5-methylbenzothiazolyl)phenyl]-6,11-diphenylnaphthacene (DBZR); 5,12-bis(4-tert-butylphenyl)naphthacene (tBDPN); 5,6,11,12-tetra-(2′-naphthalenyl)naphthacene (NR); 9,10-bis(2-naphthyl)-2-phenylanthracene; and 9-(2-naphthyl)-10-(4-phenyl)phenylanthracene.

Typical embodiments of the invention provide not only improved drive voltage but can also provide improved luminance efficiency, operational stability and color purity (chromaticity).

Unless otherwise specifically stated, use of the term “substituted” or “substituent” means any group or atom other than hydrogen. Additionally, when the term “group” is used, it means that when a substituent group contains a substitutable hydrogen, it is also intended to encompass not only the substituent's unsubstituted form, but also its form further substituted with any substituent group or groups as herein mentioned, so long as the substituent does not destroy properties necessary for device utility. Suitably, a substituent group may be halogen or may be bonded to the remainder of the molecule by an atom of carbon, silicon, oxygen, nitrogen, phosphorous, sulfur, selenium, or boron. The substituent may be, for example, halogen, such as chloro, bromo or fluoro; nitro; hydroxyl; cyano; carboxyl; or groups which may be further substituted, such as alkyl, including straight or branched chain or cyclic alkyl, such as methyl, trifluoromethyl, ethyl, t-butyl, 3-(2,4-di-t-pentylphenoxy) propyl, and tetradecyl; alkenyl, such as ethylene, 2-butene; alkoxy, such as methoxy, ethoxy, propoxy, butoxy, 2-methoxyethoxy, sec-butoxy, hexyloxy, 2-ethylhexyloxy, tetradecyloxy, 2-(2,4-di-t-pentylphenoxy)ethoxy, and 2-dodecyloxyethoxy; aryl such as phenyl, 4-t-butylphenyl, 2,4,6-trimethylphenyl, naphthyl; aryloxy, such as phenoxy, 2-methylphenoxy, alpha- or beta-naphthyloxy, and 4-tolyloxy; carbonamido, such as acetamido, benzamido, butyramido, tetradecanamido, alpha-(2,4-di-t-pentylphenoxy)acetamido, alpha-(2,4-di-t-pentylphenoxy)butyramido, alpha-(3-pentadecylphenoxy)-hexanamido, alpha-(4-hydroxy-3-t-butylphenoxy)-tetradecanamido, 2-oxo-pyrrolidin-1-yl, 2-oxo-5-tetradecylpyrrolin-1-yl, N-methyltetradecanamido, N-succinimido, N-phthalimido, 2,5-dioxo-1-oxazolidinyl, 3-dodecyl-2,5-dioxo-1-imidazolyl, and N-acetyl-N-dodecylamino, ethoxycarbonylamino, phenoxycarbonylamino, benzyloxycarbonylamino, hexadecyloxycarbonylamino, 2,4-di-t-butylphenoxycarbonylamino, phenylcarbonylamino, 2,5-(di-t-pentylphenyl)carbonylamino, p-dodecyl-phenylcarbonylamino, p-tolylcarbonyl amino, N-methylureido, N,N-dimethylureido, N-methyl-N-dodecylureido, N-hexadecylureido, N,N-dioctadecylureido, N,N-dioctyl-N′-ethylureido, N-phenylureido, N,N-diphenylureido, N-phenyl-N-p-tolylureido, N-(m-hexadecylphenyl)ureido, N,N-(2,5-di-t-pentylphenyl)-N′-ethylureido, and t-butylcarbonamido; sulfonamido, such as methylsulfonamido, benzenesulfonamido, p-tolylsulfonamido, p-dodecylbenzenesulfonamido, N-methyltetradecylsulfonamido, N,N-dipropylsulfamoylamino, and hexadecylsulfonamido; sulfamoyl, such as N-methylsulfamoyl, N-ethylsulfamoyl, N,N-dipropylsulfamoyl, N-hexadecylsulfamoyl, N,N-dimethylsulfamoyl, N-[3-(dodecyloxy)propyl]sulfamoyl, N-[4-(2,4-di-t-pentylphenoxy)butyl]sulfamoyl, N-methyl-N-tetradecylsulfamoyl, and N-dodecylsulfamoyl; carbamoyl, such as N-methylcarbamoyl, N,N-dibutylcarbamoyl, N-octadecylcarbamoyl, N-[4-(2,4-di-t-pentylphenoxy)butyl]carbamoyl, N-methyl-N-tetradecylcarbamoyl, and N,N-dioctylcarbamoyl; acyl, such as acetyl, (2,4-di-t-amylphenoxy)acetyl, phenoxycarbonyl, p-dodecyloxyphenoxycarbonyl methoxycarbonyl, butoxycarbonyl, tetradecyloxycarbonyl, ethoxycarbonyl, benzyloxycarbonyl, 3-pentadecyloxycarbonyl, and dodecyloxycarbonyl; sulfonyl, such as methoxysulfonyl, octyloxysulfonyl, tetradecyloxysulfonyl, 2-ethylhexyloxysulfonyl, phenoxysulfonyl, 2,4-di-t-pentylphenoxysulfonyl, methylsulfonyl, octylsulfonyl, 2-ethylhexylsulfonyl, dodecylsulfonyl, hexadecylsulfonyl, phenylsulfonyl, 4-nonylphenylsulfonyl, and p-tolylsulfonyl; sulfonyloxy, such as dodecylsulfonyloxy, and hexadecylsulfonyloxy; sulfinyl, such as methylsulfinyl, octylsulfinyl, 2-ethylhexylsulfinyl, dodecylsulfinyl, hexadecylsulfinyl, phenylsulfinyl, 4-nonylphenylsulfinyl, and p-tolylsulfinyl; thio, such as ethylthio, octylthio, benzylthio, tetradecylthio, 2-(2,4-di-t-pentylphenoxy)ethylthio, phenylthio, 2-butoxy-5-t-octylphenylthio, and p-tolylthio; acyloxy, such as acetyloxy, benzoyloxy, octadecanoyloxy, p-dodecylamidobenzoyloxy, N-phenylcarbamoyloxy, N-ethylcarbamoyloxy, and cyclohexylcarbonyloxy; amine, such as phenylanilino, 2-chloroanilino, diethylamine, dodecylamine; imino, such as 1 (N-phenylimido)ethyl, N-succinimido or 3-benzylhydantoinyl; phosphate, such as dimethylphosphate and ethylbutylphosphate; phosphite, such as diethyl and dihexylphosphite; a heterocyclic group, a heterocyclic oxy group or a heterocyclic thio group, each of which may be substituted and which contain a 3 to 7 membered heterocyclic ring composed of carbon atoms and at least one hetero atom selected from the group consisting of oxygen, nitrogen, sulfur, phosphorous, or boron. Such as 2-furyl, 2-thienyl, 2-benzimidazolyloxy or 2-benzothiazolyl; quaternary ammonium, such as triethylammonium; quaternary phosphonium, such as triphenylphosphonium; and silyloxy, such as trimethylsilyloxy.

If desired, the substituents may themselves be further substituted one or more times with the described substituent groups. The particular substituents used may be selected by those skilled in the art to attain desirable properties for a specific application and can include, for example, electron-withdrawing groups, electron-donating groups, and steric groups. When a molecule may have two or more substituents, the substituents may be joined together to form a ring such as a fused ring unless otherwise provided. Generally, the above groups and substituents thereof may include those having up to 48 carbon atoms, typically 1 to 36 carbon atoms and usually less than 24 carbon atoms, but greater numbers are possible depending on the particular substituents selected.

General Device Architecture

The present invention can be employed in most OLED device, configurations. These include very simple structures comprising a single anode and cathode to more complex devices, such as passive matrix displays comprised of orthogonal arrays of anodes and cathodes to form pixels, and active-matrix displays where each pixel is controlled independently, for example, with a thin film transistor (TFT).

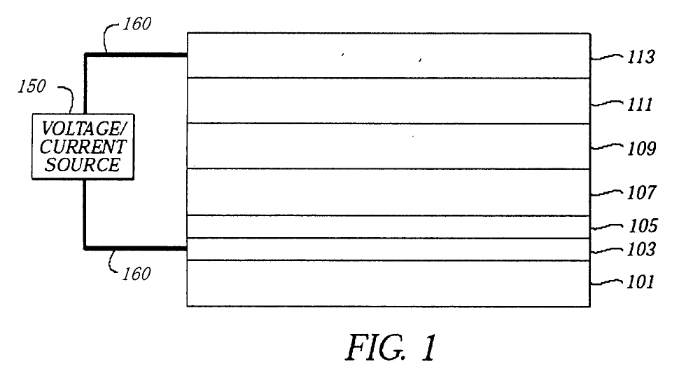

There are numerous configurations of the organic layers wherein the present invention can be successfully practiced. Essential requirements are a cathode, an anode, a HTL and a LEL. A more typical structure is shown in FIG. 1 and contains a substrate 101, an anode 103, an optional hole-injecting layer 105, a hole-transporting layer 107, a light-emitting layer 109, an electron-transporting layer 111, and a cathode 113. These layers are described in detail below. Note that the substrate may alternatively be located adjacent to the cathode, or the substrate may actually constitute the anode or cathode. Also, the total combined thickness of the organic layers is preferably less than 500 nm.

The anode and cathode of the OLED are connected to a voltage/current source 150 through electrical conductors 160. The OLED is operated by applying a potential between the anode and cathode such that the anode is at a more positive potential than the cathode. Holes are injected into the organic EL element from the anode. Enhanced device stability can sometimes be achieved when the OLED is operated in an AC mode where, for some time period in cycle, the potential bias is reversed and no current flows. An example of an AC driven OLED is described in U.S. Pat. No. 5,552,678.

Substrate

The substrate 101 can either be light transmissive or opaque, depending on the intended direction of light emission. The light transmissive property is desirable for viewing the EL emission through the substrate. Transparent glass or organic material are commonly employed in such cases. For applications where the EL emission is viewed through the top electrode, the transmissive characteristic of the bottom support is immaterial, and therefore can be light transmissive, light absorbing or light reflective. Substrates for use in this case include, but are not limited to, glass, plastic, semiconductor materials, ceramics, and circuit board materials. Of course it is necessary to provide in these device configurations a light-transparent top electrode.

Anode

The conductive anode layer 103 is commonly formed over the substrate and, when EL emission is viewed through the anode, it should be transparent or substantially transparent to the emission of interest. Common transparent anode materials used in this invention are indium-tin oxide (ITO) and tin oxide, but other metal oxides can work including, but not limited to, aluminum- or indium-doped zinc oxide (IZO), magnesium-indium oxide, and nickel-tungsten oxide. In addition to these oxides, metal nitrides, such as gallium nitride, and metal selenides, such as zinc selenide, and metal sulfides, such as zinc sulfide, can be used in layer 103. For applications where EL emission is viewed through the top electrode, the transmissive characteristics of layer 103 are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes.

Hole-Injecting Layer (HIL)

While not always necessary, it is often useful that a hole-injecting layer 105 be provided between anode 103 and hole-transporting layer 107. The hole-injecting material can serve to improve the film formation property of subsequent organic layers and to facilitate injection of holes into the hole-transporting layer. Suitable materials for use in the hole-injecting layer include, but are not limited to, porphyrinic compounds such as those described in U.S. Pat. No. 4,720,432, and plasma-deposited fluorocarbon polymers such as those described in U.S. Pat. No. 6,208,075. Alternative hole-injecting materials reportedly useful in organic EL devices are described in EP 0 891 121 A1 and EP 1 029 909 A1.

Hole-Transporting Layer (HTL)

The hole-transporting layer 107 of the organic EL device contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine group. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. No. 3,567,450 and U.S. Pat. No. 3,658,520.

A more preferred class of aromatic tertiary amines are those which include at least two aromatic tertiary amine moieties as described in U.S. Pat. No. 4,720,432 and U.S. Pat. No. 5,061,569. Such compounds include those represented by structural formula (A). 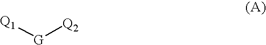
wherein Q₁ and Q₂ are independently selected aromatic tertiary amine moieties and G is a linking group such as an arylene, cycloalkylene, or alkylene group of a carbon to carbon bond. In one embodiment, at least one of Q₁ or Q₂ contains a polycyclic fused ring group, e.g., a naphthalene. When G is an aryl group, it is conveniently a phenylene, biphenylene, or naphthalene group.

A useful class of trialamine groups satisfying structural formula (A) and containing two triarylamine groups is represented by structural formula (B): 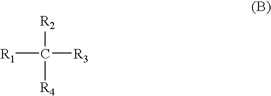
where

R₁ and R₂ each independently represents a hydrogen atom, an aryl group, or an alkyl group or R₁ and R₂ together represent the atoms completing a cycloalkyl group; and

R₃ and R₄ each independently represents an aryl group, which is in turn substituted with a diaryl substituted amino group, as indicated by structural formula (C): 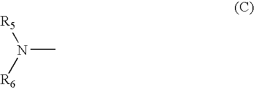
wherein R₅ and R₆ are independently selected aryl groups. In one embodiment, at least one of R₅ or R₆ contains a polycyclic fused ring group, e.g., a naphthalene.

Another class of aromatic tertiary amine groups are the tetraaryldiamines. Desirable tetraaryldiamines groups include two diarylamino groups, such as indicated by formula (C), linked through an arylene group. Useful tetraaryldiamines include those represented by formula (D). 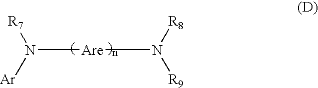
wherein

each Are is an independently selected arylene group, such as a phenylene or anthracene group,

n is an integer of from 1 to 4, and

Ar, R₇, R₈, and R₉ are independently selected aryl groups. In a typical embodiment, at least one of Ar, R₇, R₈, and R₉ is a polycyclic fused ring group, e.g., a naphthalene

The various alkyl, alkylene, aryl, and arylene groups of the foregoing structural formulae (A), (B), (C) and (D), can each in turn be substituted. Typical substituents include alkyl groups, alkoxy groups, aryl groups, aryloxy groups, and halogen such as fluoride, chloride, and bromide. The various alkyl and alkylene groups typically contain from about 1 to 6 carbon atoms. The cycloalkyl moieties can contain from 3 to about 10 carbon atoms, but typically contain five, six, or seven ring carbon atoms—e.g., cyclopentyl, cyclohexyl, and cycloheptyl ring structures. The aryl and arylene groups are usually phenyl and phenylene moieties.

The hole-transporting layer can be formed of a single or a mixture of aromatic tertiary amine compounds. Specifically, one may employ a triarylamine, such as a triarylamine satisfying the formula (B), in combination with a tetraaryldiamine, such as indicated by formula (D). When a triarylamine is employed in combination with a tetraaryldiamine, the latter is positioned as a layer interposed between the triarylamine and the electron injecting and transporting layer. Illustrative of useful aromatic tertiary amines are the following:
1,1-Bis(4-di-p-tolylaminophenyl)cyclohexane
1,1-Bis(4-di-p-tolylaminophenyl)-4-phenylcyclohexane
4,4′-Bis(diphenylamino)quadriphenyl
Bis(4-dimethylamino-2-methylphenyl)-phenylmethane
N,N,N-Tri(p-tolyl)amine
4-(di-p-tolylamino)-4′-[4(di-p-tolylamino)-styryl]stilbene
N,N,N′,N′-Tetra-p-tolyl-4-4′-diaminobiphenyl
N,N,N′,N′-Tetraphenyl-4,4′-diaminobiphenyl
N,N,N′,N′-tetra-1-naphthyl-4,4′-diaminobiphenyl
N,N,N′,N′-tetra-2-naphthyl-4,4′-diaminobiphenyl
N-Phenylcarbazole
4,4′-Bis[N-(1-naphthyl)-N-phenylamino]biphenyl(NPB)
4,4′-Bis[N-(1-naphthyl)-N-(2-naphthyl)amino]biphenyl(TNB)
4,4″-Bis[N-(1-naphthyl)-N-phenylamino]p-terphenyl
4,4′-Bis[N-(2-naphthyl)-N-phenylamino]biphenyl
4,4′-Bis[N-(3-acenaphthenyl)-N-phenylamino]biphenyl
1,5-Bis[N-(1-naphthyl)-N-phenylamino]naphthalene
4,4′-Bis[N-(9-anthryl)-N-phenylamino]biphenyl
4,4″-Bis[N-(1-anthryl)-N-phenylamino]-p-terphenyl
4,4′-Bis[N-(2-phenanthryl)-N-phenylamino]biphenyl
4,4′-Bis[N-(8-fluoranthenyl)-N-phenylamino]biphenyl
4,4′-Bis[N-(2-pyrenyl)-N-phenylamino]biphenyl
4,4′-Bis[N-(2-naphthacenyl)-N-phenylamino]biphenyl
4,4′-Bis[N-(2-perylenyl)-N-phenylamino]biphenyl
4,4′-Bis[N-(1-coronenyl)-N-phenylamino]biphenyl
2,6-Bis(di-p-tolylamino)naphthalene
2,6-Bis[di-(1-naphthyl)amino]naphthalene
2,6-Bis[N-(1-naphthyl)-N-(2-naphthyl)amino]naphthalene
N,N,N′,N′-Tetra(2-naphthyl)-4,4′-diamino-p-terphenyl
4,4′-Bis {N-phenyl-N-[4-(1-naphthyl)-phenyl]amino}biphenyl
4,4′-Bis[N-phenyl-N-(2-pyrenyl)amino]biphenyl
2,6-Bis[N,N-di(2-naphthyl)amine]fluorene
1,5-Bis[N-(1-naphthyl)-N-phenylamino]naphthalene
4,4′,4″-tris[(3-methylphenyl)phenylamino]triphenylamine (MTDATA)
4,4′-Bis[N-(3-methylphenyl)-N-phenylamino]biphenyl (TPD

Another class of useful hole-transporting materials includes polycyclic aromatic compounds as described in EP 1 009 041. In addition, polymeric hole-transporting materials can be used such as poly(N-vinylcarbazole) (PVK), polythiophenes, polypyrrole, polyaniline, and copolymers such as poly(3,4-ethylenedioxythiophene)poly(4-styrenesulfonate) also called PEDOT/PSS.

Light-Emitting Layer (LEL)

As more fully described in U.S. Pat. Nos. 4,769,292 and 5,935,721, the light-emitting layer (LEL) 109 of the organic EL element comprises a luminescent or fluorescent material where electroluminescence is produced as a result of electron-hole pair recombination in this region. The light-emitting layer can be comprised of a single material, but more commonly consists of non-electroluminescent compounds doped with an electroluminescent guest compound or compounds where light emission comes primarily from the electroluminescent compound and can be of any color. The non-electroluminescent compound or compounds in the light-emitting layer can be an electron-transporting material, as defined below, a hole-transporting material, as defined above, or another material or combination of materials that support hole-electron recombination. The electroluminescent compound is usually chosen from highly fluorescent dyes, but phosphorescent compounds, e.g., transition metal complexes as described in WO 98/55561, WO 00/18851, WO 00/57676, and WO 00/70655 are also useful. Electroluminescent compounds are typically coated as 0.01 to 10% into the non-electroluminescent component material.

An important relationship for choosing a dye as a electroluminescent component is a comparison of the bandgap potential which is defined as the energy difference between the highest occupied molecular orbital and the lowest unoccupied molecular orbital of the molecule. For efficient energy transfer from the non-electroluminescent compound to the electroluminescent compound molecule, a necessary condition is that the band gap of the electroluminescent compound is smaller than that of the non-electroluminescent compound or compounds.

Non-electroluminescent compounds and emitting molecules known to be of use include, but are not limited to, those disclosed in U.S. Pat. No. 4,768,292, U.S. Pat. No. 5,141,671, U.S. Pat. No. 5,150,006, U.S. Pat. No. 5,151,629, U.S. Pat. No. 5,405,709, U.S. Pat. No. 5,484,922, U.S. Pat. No. 5,593,788, U.S. Pat. No. 5,645,948, U.S. Pat. No. 5,683,823, U.S. Pat. No. 5,755,999, U.S. Pat. No. 5,928,802, U.S. Pat. No. 5,935,720, U.S. Pat. No. 5,935,721, and U.S. Pat. No. 6,020,078.

Metal complexes of 8-hydroxyquinoline and similar derivatives (Formula E) constitute one class of useful non-electroluminescent component compounds capable of supporting electroluminescence, and are particularly suitable for light emission of wavelengths longer than 500 nm, e.g., green, yellow, orange, and red. 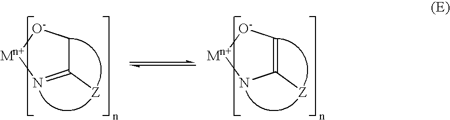
wherein

M represents a metal;

n is an integer of from 1 to 4; and

Z independently in each occurrence represents the atoms completing a nucleus having at least two fused aromatic rings.

From the foregoing it is apparent that the metal can be monovalent, divalent, trivalent, or tetravalent metal. The metal can, for example, be an alkali metal, such as lithium, sodium, or potassium; an alkaline earth metal, such as magnesium or calcium; an earth metal, such as aluminum or gallium, or a transition metal such as zinc or zirconium. Generally any monovalent, divalent, trivalent, or tetravalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:

CO-1: Aluminum trisoxine [alias, tris(8-quinolinolato)aluminum(III)]

CO-2: Magnesium bisoxine [alias, bis(8-quinolinolato)magnesium(II)]

CO-3: Bis[benzo {f}-8-quinolinolato]zinc (II)

CO-4: Bis(2-methyl-8-quinolinolato)aluminum(III)-μ-oxo-bis(2-methyl-8-quinolinolato) aluminum(III)

CO-5: Indium trisoxine [alias, tris(8-quinolinolato)indium]

CO-6: Aluminum tris(5-methyloxine) [alias, tris(5-methyl-8-quinolinolato) aluminum(III)]

CO-7: Lithium oxine [alias, (8-quinolinolato)lithium(I)]

CO-8: Gallium oxine [alias, tris(8-quinolinolato)gallium(III)]

CO-9: Zirconium oxine [alias, tetra(8-quinolinolato)zirconium(IV)]

CO-10: Bis(2-methyl-8-quinolinato)-4-phenylphenolatoaluminum (III)

Derivatives of 9,10-di-(2-naphthyl)anthracene (Formula F) constitute one class of useful non-electroluminescent compounds capable of supporting electroluminescence, and are particularly suitable for light emission of wavelengths longer than 400 nm, e.g., blue, green, yellow, orange or red. 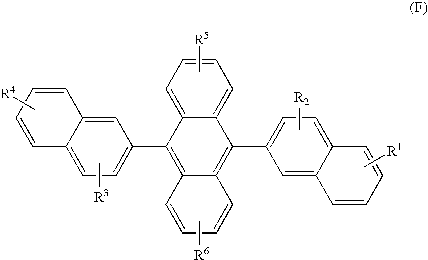
wherein: R¹, R², R³, R⁴, R⁵, and R⁶ represent hydrogen or one or more substituents selected from the following groups:

Group 1: hydrogen, alkyl and alkoxy groups typically having from 1 to 24 carbon atoms;

Group 2: a ring group, typically having from 6 to 20 carbon atoms;

Group 3: the atoms necessary to complete a carbocyclic fused ring group such as naphthyl, anthracenyl, pyrenyl, and perylenyl groups, typically having from 6 to 30 carbon atoms;

Group 4: the atoms necessary to complete a heterocyclic fused ring group such as furyl, thienyl, pyridyl, and quinolinyl groups, typically having from 5 to 24 carbon atoms;

Group 5: an alkoxylamino, alkylamino, and arylamino group typically having from 1 to 24 carbon atoms; and

Group 6: fluorine, chlorine, bromine and cyano radicals.

Illustrative examples include 9,10-di-(2-naphthyl)anthracene and 2-t-butyl-9,10-di-(2-naphthyl)anthracene. Other anthracene derivatives can be useful as non-electroluminescent compound(s) in the LEL, including derivatives of 9,10-bis[4-(2,2-diphenylethenyl)phenyl]anthracene, and phenylanthracene derivatives as described in EP 681,019.

Benzazole derivatives (Formula G) constitute another class of useful non-electroluminescent components capable of supporting electroluminescence, and are particularly suitable for light emission of wavelengths longer than 400 nm, e.g., blue, green, yellow, orange or red. 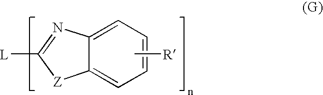
where:

n is an integer of 3 to 8;

Z is —O, —NR or —S where R is H or a substituent; and

R′ represents one or more optional substituents where R and each R′ are H or alkyl groups such as propyl, t-butyl, and heptyl groups typically having from 1 to 24 carbon atoms; carbocyclic or heterocyclic ring groups such as phenyl and naphthyl, furyl, thienyl, pyridyl, and quinolinyl groups and atoms necessary to complete a fused aromatic ring group typically having from 5 to 20 carbon atoms; and halo such as chloro, and fluoro;

L is a linkage unit usually comprising an alkyl or ary group which conjugately or unconjugately connects the multiple benzazoles together.

An example of a useful benzazole is 2, 2′, 2″-(1,3,5-phenylene)tris[1-phenyl-1H-benzimidazole], (TPBI).

Distyrylarylene derivatives as described in U.S. Pat. No. 5,121,029 are also useful non-electroluminescent component materials in the LEL.

Desirable fluorescent electroluminescent components include groups derived from fused ring, heterocyclic and other compounds such as anthracene, tetracene, xanthene, perylene, rubrene, pyran, rhodamine, quinacridone, dicyanomethylenepyran, thiopyran, polymethine, pyrilium thiapyrilium, and carbostyryl compounds. Illustrative examples of useful electroluminescent components include, but are not limited to, the following:

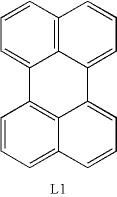

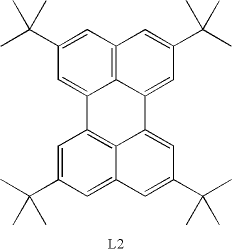

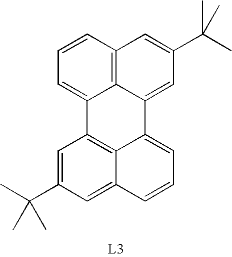

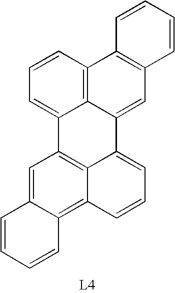

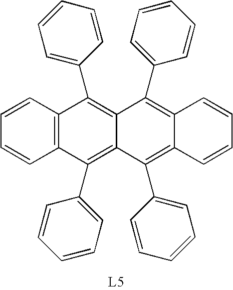

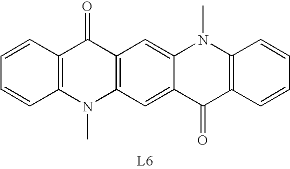

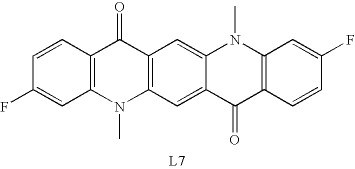

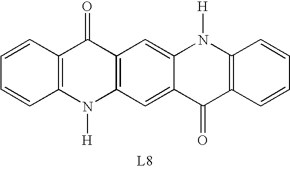

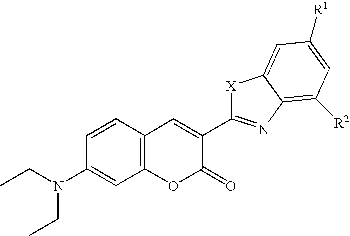

| | X | R1 | R2 |
|---|---|---|---|
| L9 | O | H | H |
| L10 | O | H | Methyl |
| L11 | O | Methyl | H |
| L12 | O | Methyl | Methyl |
| L13 | O | H | t-butyl |
| L14 | O | t-butyl | H |
| L15 | O | t-butyl | t-butyl |
| L16 | S | H | H |
| L17 | S | H | Methyl |
| L18 | S | Methyl | H |
| L19 | S | Methyl | Methyl |
| L20 | S | H | t-butyl |
| L21 | S | t-butyl | H |
| L22 | S | t-butyl | t-butyl |

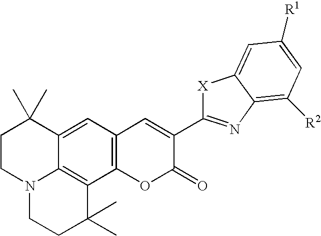

| | X | R1 | R2 |
|---|---|---|---|
| L23 | O | H | H |
| L24 | O | H | Methyl |
| L25 | O | Methyl | H |
| L26 | O | Methyl | Methyl |
| L27 | O | H | t-butyl |
| L28 | O | t-butyl | H |
| L29 | O | t-butyl | t-butyl |
| L30 | S | H | H |
| L31 | S | H | Methyl |
| L32 | S | Methyl | H |
| L33 | S | Methyl | Methyl |
| L34 | S | H | t-butyl |
| L35 | S | t-butyl | H |
| L36 | S | t-butyl | t-butyl |

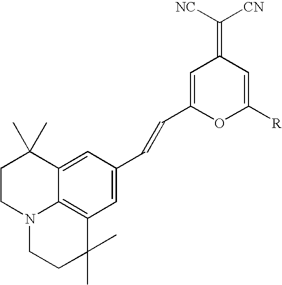

R

| | |
|---|---|
| L37 | phenyl |
| L38 | methyl |
| L39 | t-butyl |
| L40 | mesityl |

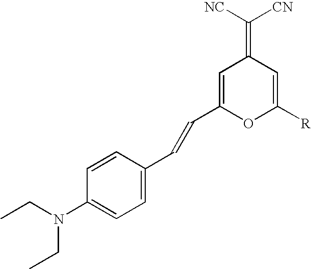

R

| | |
|---|---|
| L41 | phenyl |
| L42 | methyl |
| L43 | t-butyl |
| L44 | mesityl |

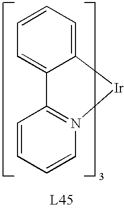

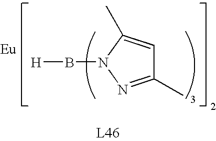

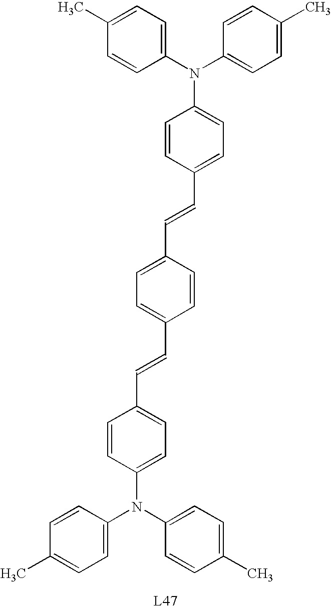

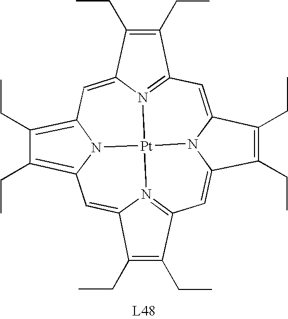

Electron-Transporting Layer (ETL)

Preferred thin film-forming materials for use in forming the electron-transporting layer 111 of the organic EL devices of this invention are metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural formula (E), previously described.

Other electron-transporting materials include various butadiene derivatives as disclosed in U.S. Pat. No. 4,356,429 and various heterocyclic optical brighteners as described in U.S. Pat. No. 4,539,507. Benzazoles satisfying structural formula (G) are also useful electron transporting materials.

In some instances, layers 109 and 111 can optionally be collapsed into a single layer that serves the function of supporting both light emission and electron transportation.

Cathode

When light emission is through the anode, the cathode layer 113 used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bilayers comprised of a thin layer of a low work function metal or metal salt capped with a thicker layer of conductive metal. One such cathode is comprised of a thin layer of LiF followed by a thicker layer of Al as described in U.S. Pat. No. 5,677,572. Other useful cathode materials include, but are not limited to, those disclosed in U.S. Pat. No. 5,059,861, U.S. Pat. No. 5,059,862, and U.S. Pat. No. 6,140,763.

When light emission is viewed through the cathode, the cathode must be transparent or nearly transparent. For such applications, metals must be thin or one must use transparent conductive oxides, or a combination of these materials. Optically transparent cathodes have been described in more detail in U.S. Pat. No. 5,776,623. Cathode materials can be deposited by evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Deposition of Organic Layers

The organic materials mentioned above are suitably deposited through sublimation, but can be deposited from a solvent with an optional binder to improve film formation. If the material is a polymer, solvent deposition is usually preferred. The material to be deposited by sublimation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. No. 5,851,709 and U.S. Pat. No. 6,066,357) and inkjet method (U.S. Pat. No. 6,066,357).

Organic materials useful in making OLEDs, for example organic hole-transporting materials, organic light-emitting materials doped with an organic electroluminescent components have relatively complex molecular structures with relatively weak molecular bonding forces, so that care must be taken to avoid decomposition of the organic material(s) during physical vapor deposition. The aforementioned organic materials are synthesized to a relatively high degree of purity, and are provided in the form of powders, flakes, or granules. Such powders or flakes have been used heretofore for placement into a physical vapor deposition source wherein heat is applied for forming a vapor by sublimation or vaporization of the organic material, the vapor condensing on a substrate to provide an organic layer thereon.

Several problems have been observed in using organic powders, flakes, or granules in physical vapor deposition: These powders, flakes, or granules are difficult to handle. These organic materials generally have a relatively low physical density and undesirably low thermal conductivity, particularly when placed in a physical vapor deposition source which is disposed in a chamber evacuated to a reduced pressure as low as 10⁻⁶ Torr. Consequently, powder particles, flakes, or granules are heated only by radiative heating from a heated source, and by conductive heating of particles or flakes directly in contact with heated surfaces of the source. Powder particles, flakes, or granules which are not in contact with heated surfaces of the source are not effectively heated by conductive heating due to a relatively low particle-to-particle contact area; This can lead to nonuniform heating of such organic materials in physical vapor deposition sources. Therefore, result in potentially nonuniform vapor-deposited organic layers formed on a substrate.

These organic powders can be consolidating into a solid pellet. These solid pellets consolidating into a solid pellet from a mixture of a sublimable organic material powder are easier to handle. Consolidation of organic powder into a solid pellet can be accomplished with relatively simple tools. A solid pellet formed from mixture comprising one or more non-luminescent organic non-electroluminescent component materials or luminescent electroluminescent component materials or mixture of non-electroluminescent component and electroluminescent component materials can be placed into a physical vapor deposition source for-making organic layer. Such consolidated pellets can be used in a physical vapor deposition apparatus.

In one aspect, the present invention provides a method of making an organic layer from compacted pellets of organic materials on a substrate, which will form part of an OLED.

Encapsulation

Most OLED devices are sensitive to moisture and/or oxygen so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890.

Hole Blocking Layer

Some OLED devices require a Hole-Blocking Layer to either facilitate injection of electrons into the. LEL or attenuate the passage of holes into the ETL to ensure recombination in the LEL (D. F. O'brien, M. A. Baldo, M. E. Thompson, and S. R. Forrest Appl. Phys. Lett. 74, 442 (1999)). Typically this layer is thin (i.e., 10 nm) and it is located between the LEL and ETL.

Band Gap

An important relationship exists when selecting an electroluminescent compound. A comparison of the bandgap potential with respect to the bandgap(s) of the non-electroluminescent compound(s) in the LEL material must be carefully considered. In order for there to be efficient energy transfer from the non-electroluminescent compound to the electroluminescent component molecule, the band gap of the electroluminescent compound is typically smaller than that of the non-electroluminescent component material.

The bandgaps are typically determined experimentally by UVS or XPS spectroscopic techniques to characterize the energy levels and chemical nature of the HTL, LEL and ETL layers. All bandgaps as pertaining to this application are determined by the following procedure:
1. the absorption and emission spectra for a material are measured in a nonpolar solvent such as ethylacetate or toluene at low (i.e., <1×10⁻³M) concentration and optical density (i.e., <0.2) bandgaps.
2. the spectra are normalized to one via the maximum absorption and emission bands in the visible region (i.e., 350-750 nm) of the spectrum.
3. the normalized absorption and emission spectra are plotted on the same chart.

4. the wavelength between the normalized absorption and emission spectra where they cross (crossing-wavelength) is defined as E_{0,0} and this “optical” bandgap otherwise known in the art as the energy difference between the highest occupied molecular orbital (HOMO) level or the maximum level of the valence band and the lowest unoccupied molecular orbital (LUMO) level or the minimum level of the conducting band. This value is typically reported in eV and that conversion is made by dividing the “crossing-wavelength” into 1240 eV nm.

Optical Bandgaps for Representative Materials

| Invention | Bandgap (eV) |
|---|---|
| Inv-1 | 2.12 eV |
| Inv-12 | 2.22 eV |
| Inv-19 | 2.31 eV |
| Inv-20 | 2.27 eV |
| Inv-21 | 2.28 eV |
| Inv-22 | 3.04 eV |
| Inv-23 | 2.51 eV |
| Inv-24 | 3.15 eV |
| Inv-26 | 2.76 eV |

The invention and its advantages are further illustrated by the specific examples that follow. The term “percentage” or “percent” and the symbol “%” indicate the volume percent (or a thickness ratio as measured on a thin film thickness monitor) of a particular electroluminescent or non-electroluminescent compound of the total material in the light-emitting layer. If more than one electroluminescent or non-electroluminescent compound is present the total volume of the electroluminescent or non-electroluminescent compounds can also be expressed as a percentage of the total material in the light-emitting layer. Volume percent can be converted to weight percent by employing the equation d=m/v, which gives the relationship between density d, mass m, and volume v.

The entire contents of the patents and other publications referred to in this specification are incorporated herein by reference.

### EXAMPLES

The inventions and its advantages are further illustrated by the specific examples, which follow.

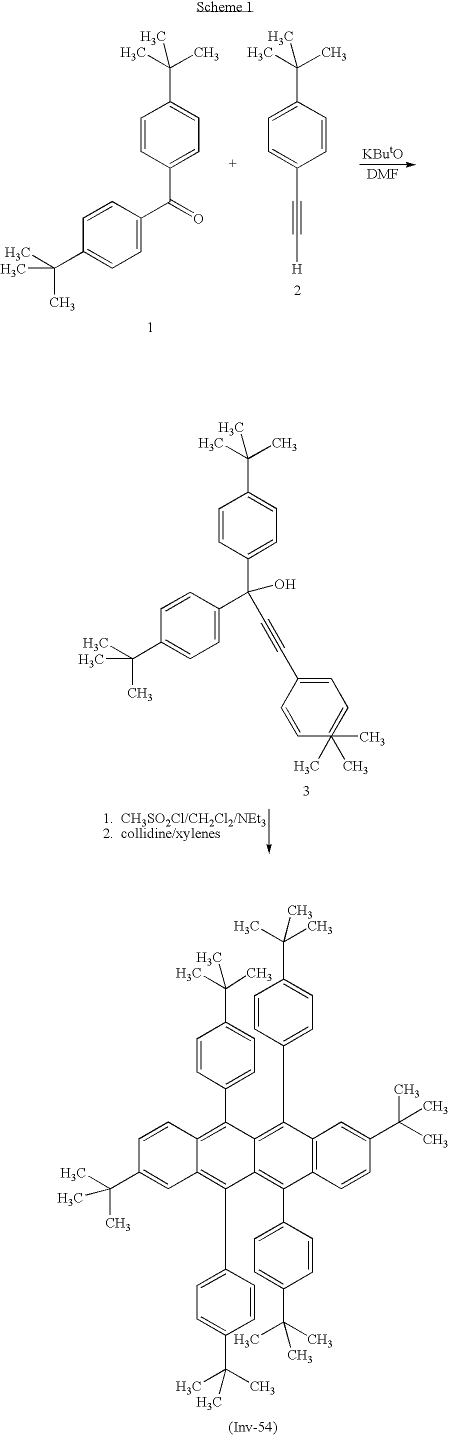

### Example 1

### Synthesis (Scheme 1)

Preparation of compound (3): Under a nitrogen atmosphere, acetylenic compound (2) (2.0 g, 12 mMole), was dissolved in dimethylformamide (DMF) (100 mL) and the solution cool to 0° C. Potassium t-butoxide (KBu^{t}O) (1.4 g, 12 mMole), was added and the mixture stirred well for approximately 15 minutes. To this mixture was then added the benzophenone (1) (3.53 g, 30 mMole). Stirring was continued at 0° C. for approximately 30 minutes and then allowed to come to room temperature over a 1-hour period. At the end of this time the solution was cooled to 0° C. and the reaction treated with saturated sodium chloride (20 mL). The mixture was then diluted with ethyl acetate, washed with 2N-HCl (×3), dried over MgSO₄, filtered and concentrated under reduced pressure. The crude product was triturated with petroleum ether to give the product as an off-white solid. Yield of compound (3), 3.0 g.

Preparation of Inventive Compound, Inv-54: Compound (3) (7.0 g, 15 mMole) was dissolved in methylene chloride (CH₂Cl₂) (70 mL), and stirred at 0° C. under a nitrogen atmosphere. To this solution was added triethylamine (NEt₃) (1.56 g, 15 mMole) and then treated drop by drop with methanesulfonyl chloride (CH₃SO₂Cl) (1.92 g, 15 mMole), keeping the temperature of the reaction in the range 0-5° C. After the addition the solution was stirred at 0° C. for 30 minutes and then allowed to warm to room temperature over 1 hour. The reaction was then heated to reflux, distilling off the methylene chloride solvent and gradually replacing it with xylenes (a total of 70 mL). When the internal temperature of the reaction reached 80° C., collidine (2.40 g, 19.82 mMole), dissolved in xylenes (10 mL) was added drop by drop over a 10-minute period. The temperature was then raised to 110° C. and held at this temperature for 4 hours. After this period the reaction was cooled and concentrated under reduced pressure. The oily residue was stirred with methanol (70 mL) to give the crude product. This material was filtered off, washed with methanol and petroleum ether to give inventive compound Inv-54 as a bright red solid. Yield 1.5 g with a melting point of 300-305° C. The product may be further purified by sublimation (250° C. @ 200 millitorr) with a N₂ carrier gas.

The comparative compounds used in the invention are as follows:

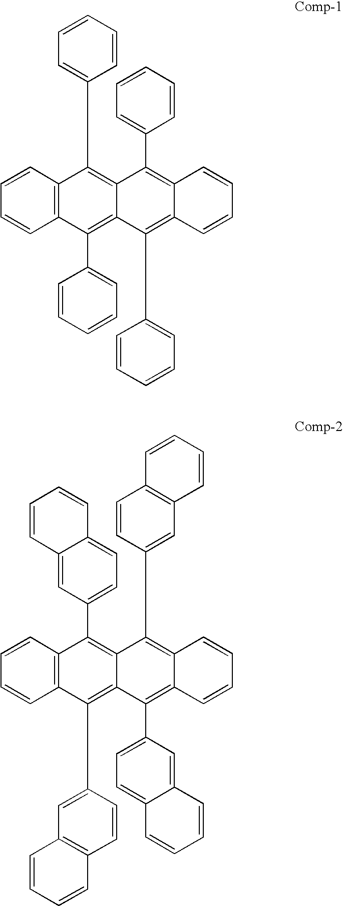

Comp-1 is the parent rubrene and falls outside the scope of the current invention. It is well known to those in the art and has no substituents at the 2- and 8-positions on either of the end rings of the naphthacene nucleus, nor on the four phenyl rings located on the center rings of the naphthacene. It is found as the host in Example 3 of U.S. Pat. No. 6,613,454. Comp-2, 5,6,11,12-tetra-(2′-naphthalenyl)naphthacene (NR), also falls outside the scope of the current invention. It has four 2-naphthyl groups in the 5-, 6-, 11- and 12-positions of the naphthacene nucleus, has no substituents at the 2- and 8-positions and is compound IB-81 in U.S. Pat. No. 6,613,454. In the following Example 2, Inv-1 and Inv-9 are electroluminescent compounds with the first bandgap, ELC-1. Inv-54 and Inv-55 are non-electroluminescent compounds with the second bandgap, non-ELC-2. Inv-26 is a non-electroluminescent compound with the further bandgap, non-ELC-3. Comp-1 and Comp-2 are comparison compounds and are also non-electroluminescent compounds with second bandgaps, non-ELC-2.

### Example 2

### EL Device Fabrication—Inventive and Comparative Examples

An EL device satisfying the requirements of the invention was constructed as Sample 1 in the following manner:

A glass substrate coated with an 85 nm layer of indium-tin oxide (ITO) as the anode was sequentially ultrasonicated in a commercial detergent, rinsed in deionized water, degreased in toluene vapor and exposed to oxygen plasma for about 1 min.

a) Over the ITO was deposited a 1 nm fluorocarbon (CFₓ) hole-injecting layer (HIL) by plasma-assisted deposition of CHF₃.

b) A hole-transporting layer (HTL) of N,N′-di-1-naphthalenyl-N,N′-diphenyl-4,4′-diaminobiphenyl (NPB) having a thickness of 150 nm was then evaporated onto a).

c) A 37.5 nm light-emitting layer (LEL) of the non-ELCs, tris(8-quinolinolato)aluminum (III) (AlQ₃, Inv-26) and Inv-55, and the ELC, Inv-1 (see Tables 1 and 2 for concentration expressed as %.) were then deposited onto the hole-transporting layer.

d) A 37.5 nm electron-transporting layer (ETL) of tris(8-quinolinolato)aluminum (III) (AlQ₃, Inv-26) was then deposited onto the light-emitting layer.

e) On top of the AlQ₃ layer was deposited a 220 nm cathode formed of a 10:1 volume ratio of Mg and Ag.

The above sequence completed the deposition of the EL device. The device was then hermetically packaged in a dry glove box for protection against ambient environment.

The results for Example 2 are recorded in Tables 1, 2, 3 and 4 as Samples 1-6.

Samples 2 and 3 of Tables 1 and 2 are comparison EL devices, fabricated in an identical manner to Sample 1, but incorporating comparison compounds Comp-1 and Comp-2 respectively, in place of Inv-55 and at the same nominal levels as Inv-55.

Sample 4 of Tables 3 and 4 is the EL device of the invention incorporating ELC Inv-9, with non-ELCs Inv-54 and Inv-26 and fabricated in an identical manner to Sample 1.

Sample 5 of Tables 3 and 4 is the EL device of the invention incorporating ELC Inv-9, with non-ELCs Inv-55 and Inv-26, and fabricated in an identical manner to Sample 1.

Sample 6 of Tables 3 and 4 is a comparison EL device incorporating ELC Inv-9, with non-ELCs Comp-2 and Inv-26, and fabricated in an identical manner to Sample 1.

Tables 1 and 3 refer to, the luminance behavior of the samples while Tables 2 and 4 refer to the stability behavior of the samples.

TABLE 1
Evaluation Results for EL devices Containing Electroluminescent
Compound, Inv-1 and Non-Electroluminescent Compounds.

| | | ELC-1 | Non-ELC-2 | Non-ELC-3 | Yield |
|---|---|---|---|---|---|
| Sample | Type | % Conc. | % Conc. | % Conc. | (cd/A)¹ |
| 1 | Inventive | Inv-1 | Inv-55 | Inv-26 | |
| | | 0.5 | 5 | 94.5 | 4.39 |
| | | | 10 | 89.5 | 4.12 |
| | | | 25 | 74.5 | 4.24 |
| 2 | Comparative | Inv-1 | Comp-1 | Inv-26 | |
| | | 0.5 | 5 | 94.5 | 3.14 |
| | | | 10 | 89.5 | 3.44 |
| | | | 25 | 74.5 | 4.61 |
| 3 | Comparative | Inv-1 | Comp-2 | Inv-26 | |
| | | 0.5 | 5 | 94.5 | 2.09 |
| | | | 10 | 89.5 | 2.42 |
| | | | 25 | 74.5 | 3.22 |

¹Luminance yields and efficiencies reported at 20 mA/cm².

TABLE 2
Stability Results for EL devices Containing Electroluminescent
Compound, Inv-1 and Non-Electroluminescent Compounds.

| | | ELC-1 | Non-ELC-2 | Non-ELC-3 | Sta- |
|---|---|---|---|---|---|
| Sample | Type | % Conc. | % Conc. | % Conc. | bility² |
| 1 | Inventive | Inv-1 | Inv-55 | Inv-26 | |
| | | 0.5 | 5 | 94.5 | 96 |
| | | | 10 | 89.5 | 97 |
| | | | 25 | 74.5 | 95 |
| 2 | Comparative | Inv-1 | Comp-1 | Inv-26 | |
| | | 0.5 | 5 | 94.5 | 93 |
| | | | 10 | 89.5 | 92 |
| | | | 25 | 74.5 | 88 |

²Stability refers to the % of luminance remaining after the device has operated for 200 hours at 70° C. with a current density of 20 mA/cm².

TABLE 3
Evaluation Results for EL devices Containing Electroluminescent
Compound, Inv-9 and Non-Electroluminescent Compounds.

| | | ELC-1 | Non-ELC-2 | Non-ELC-3 | Yield |
|---|---|---|---|---|---|
| Sample | Type | % Conc. | % Conc. | % Conc. | (cd/A)¹ |
| 4 | Inventive | Inv-9 | Inv-54 | Inv-26 | |
| | | 0.5 | 5 | 94.5 | 4.18 |
| | | | 10 | 89.5 | 3.79 |
| | | | 25 | 74.5 | 3.37 |
| | | | 50 | 49.5 | 2.97 |
| | | | 75 | 24.5 | 2.57 |
| 5 | Inventive | Inv-9 | Inv-55 | Inv-26 | |
| | | 0.5 | 5 | 94.5 | 4.30 |
| | | | 10 | 89.5 | 3.75 |
| | | | 25 | 74.5 | 3.33 |
| | | | 50 | 49.5 | 2.74 |
| | | | 75 | 24.5 | 2.26 |
| 6 | Comparative | Inv-9 | Comp-2 | Inv-26 | |
| | | 0.5 | 5 | 94.5 | 2.38 |
| | | | 10 | 89.5 | 2.45 |
| | | | 25 | 74.5 | 2.73 |
| | | | 50 | 49.5 | 2.59 |
| | | | 75 | 24.5 | 2.62 |

¹Luminance yields and efficiencies reported at 20 mA/cm².

TABLE 4
Stability Results for EL devices Containing Electroluminescent
Compound, Inv-9 and Non-Electroluminescent Compounds.

| | | ELC-1 | Non-ELC-2 | Non-ELC-3 | Sta- |
|---|---|---|---|---|---|
| Sample | Type | % Conc. | % Conc. | % Conc. | bility² |
| 4 | Inventive | Inv-9 | Inv-54 | Inv-26 | |
| | | 0.5 | 5 | 94.5 | 65 |
| | | | 10 | 89.5 | 63 |
| 5 | Inventive | Inv-9 | Inv-55 | Inv-26 | |
| | | 0.5 | 5 | 94.5 | 61 |
| | | | 10 | 89.5 | 62 |
| 6 | Comparative | Inv-9 | Comp-2 | Inv-26 | |
| | | 0.5 | 5 | 94.5 | 55 |
| | | | 10 | 89.5 | 57 |

²Stability refers to the % of luminance remaining after the device has operated for 200 hours at 70° C. with a current density of 20 mA/cm².

As can be seen from Tables 1 and 3, the EL devices of the invention Samples 1, 4 and 5 consistently show superior luminance over the comparison EL devices of Samples 2, 3 and 6, at all coated levels of the electroluminescent and non-electroluminescent compounds. In addition, Tables 2 and 4 show that the operational stability of the EL devices of the invention are also consistently superior to those of the comparison EL devices.

The invention has been described in detail with particular reference to certain preferred embodiments thereof, but it will be understood that variations and modifications can be effected within the spirit and scope of the invention. For example, multiple electroluminescent compounds and multiple non-electroluminescent compounds can be used in any of the hole-transporting, electron-transporting or light-emitting layers.

The patents and other publications referred to are incorporated herein in their entirety.

### PARTS LIST

101 Substrate
103 Anode
105 Hole-Injecting layer (HIL)
107 Hole-Transporting layer (HTL)
109 Light-Emitting layer (LEL)
111 Electron-Transporting layer (ETL)
113 Cathode
150 Power Source
160 Conductor

1. An OLED device comprising a light emitting layer containing an electroluminescent component having a first bandgap, a non-electroluminescent component having a second bandgap, and one or more further non-electroluminescent components having further bandgaps, wherein:
i) the second bandgap is equal to or greater than the first bandgap but is not more than 2.7 eV;
ii) each of the one or more further bandgap is greater than the first and second bandgaps;
iii) the non-electroluminescent component with the second bandgap is present in an amount of 0.1 to 99.8 vol. percent of the total material in the light emitting layer;
iv) the one or more non-electroluminescent components with further bandgaps are present in a combined amount of 0.1 to 99.8 vol percent of the total material in the light emitting layer;
v) the electroluminescent component is present in an amount of 0.1 to 5 vol. percent of the total material in the light emitting layer; and
vi) the non-electroluminescent component with the second bandgap is represented by formula (Ia); 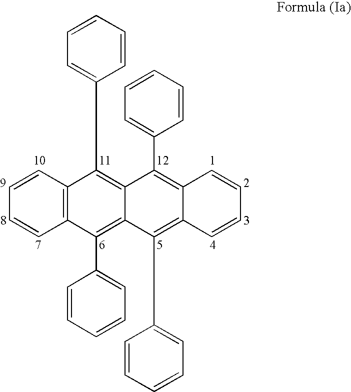
wherein:
a) any hydrogen on the phenyl rings in the 6- and 12-positions may be substituted;
b) there are identical substituent groups at the 2- and 8-positions; and
c) the phenyl rings in the 5- and 11-positions contain only para-substituents identical to the substituent groups in paragraph b).

2. The OLED device of claim 1 wherein the light emitting layer contains more than one electroluminescent component.

3. The OLED device of claim 1 wherein the electroluminescent component with the first bandgap is a periflanthene compound represented by formula (II): 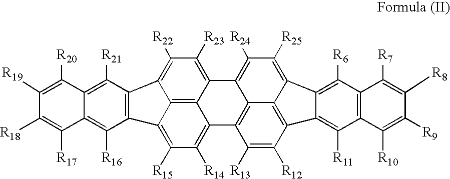
wherein:
R₆, R₇, R₈, R₉, R₁₀, R₁₁, R₁₂, R₁₃, R₁₄, R₁₅, R₁₆, R₁₇, R₁₈, R₁₉, R₂₀, R₂₁, R₂₂, R₂₃, R₂₄, R₂₅ are independently selected as hydrogen or substituents;
provided that any of the R₆ through R₂₅ substituents may join to form further fused rings.

4. The OLED device of claim 3 wherein at least one R₆, R₇, R₈, R₉, R₁₀, R₁₁, R₁₂, R₁₃, R₁₄, R₁₅, R₁₆, R₁₇, R₁₈, R₁₉, R₂₀, R₂₁, R₂₂, R₂₃, R₂₄ and R₂₅ are independently selected from the group consisting of halide, alkyl, aryl, alkoxy and aryloxy groups.

5. The OLED device of claim 4 wherein at least one substituent is a phenyl group.

6. The OLED device of claim 1 wherein the non-electroluminescent component with the second bandgap is represented by formula (Ib); 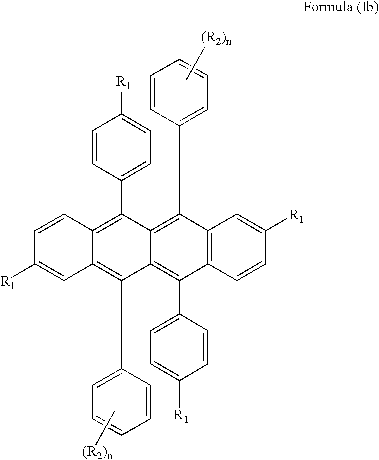
wherein
R₁ and R₂ are substituent groups;
n is 1-5;
provided that the R₁ groups are the same; and
provided further, that the R₂ groups, their location and n value on one ring are the same as those on the second ring.

7. The OLED device of claim 6 wherein R₁ is represented by the formula; 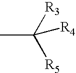
wherein each of R₃, R₄ and R₅ is hydrogen or an independently selected substituent or R₃, R₄ and R₅ taken together can form a mono- or multi-cyclic ring system.

8. The OLED device of claim 3 wherein the non-electroluminescent component with the second bandgap is at least 5 vol. percent of the total material in the light emitting layer.

9. The OLED device of claim 3 wherein the non-electroluminescent component with the second bandgap is in the range of 5 to 95 vol. percent of the total material in the light emitting layer.

10. The OLED device of claim 3 wherein the non-electroluminescent component with the second bandgap is in the range of 10 to 75 vol. percent of the total material in the light emitting layer.

11. The OLED device of claim 3 wherein the periflanthene compound is represented by one of the following formulae:

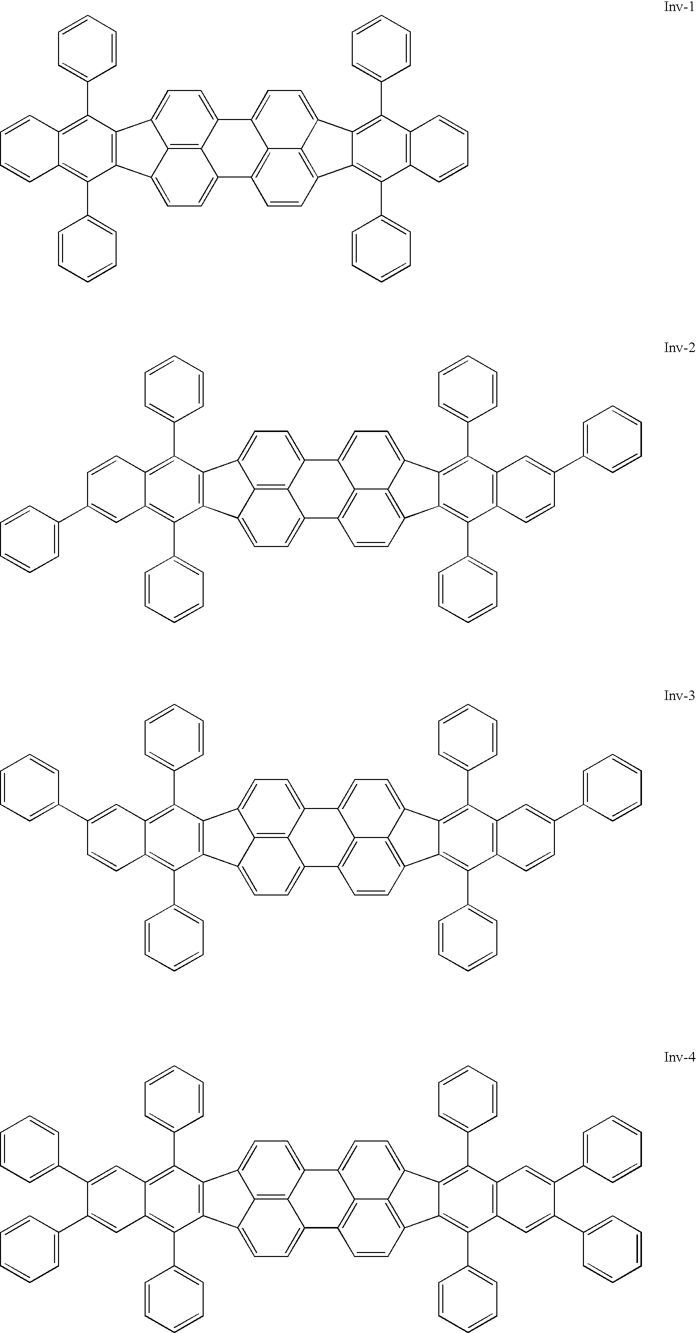

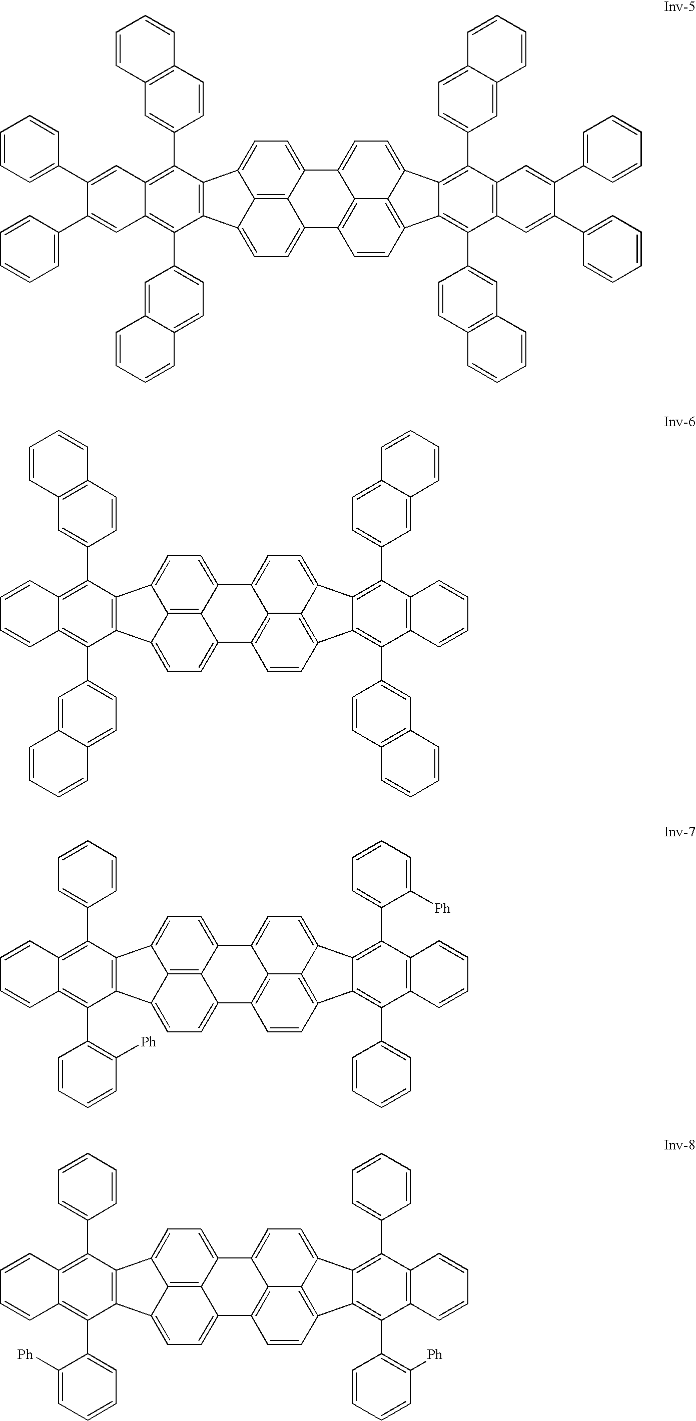

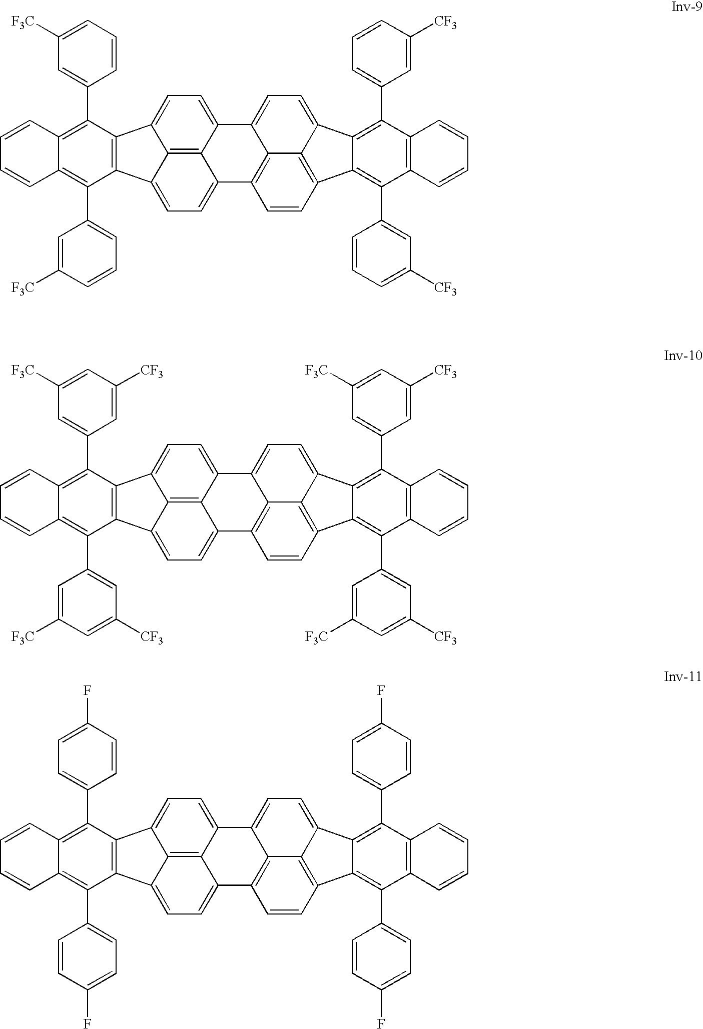

12. The OLED device of claim 3 wherein the electroluminescent component with the first bandgap is in the range of 0.1 to 5 vol. percent of the total material in the light emitting layer.

13. The OLED device of claim 3 wherein the electroluminescent component with the first bandgap is in the range of 0.3 to 1.5 vol. percent of the total material in the light emitting layer.

14. The OLED device of claim 3 wherein the electroluminescent component with the first bandgap is represented by formulae Inv-1 and Inv-9:

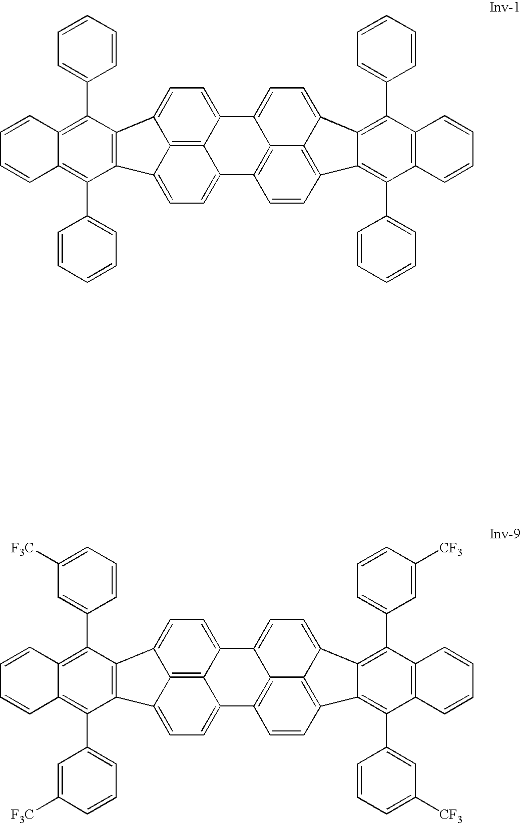

15. The OLED device of claim 1 wherein the electroluminescent component with the first bandgap is a pyran derivative represented by formula (III): 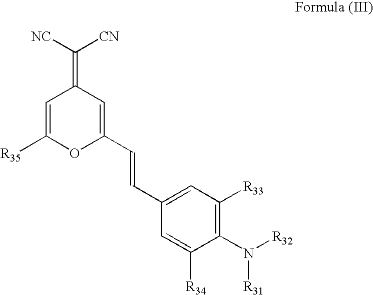
wherein:
R₃₁, R₃₂, R₃₃, R₃₄, and R₃₅ are independently selected as hydrogen or substituents;
provided that any of the indicated substituents may join to form further fused rings.

16. The OLED device of claim 15 wherein R₃₁, R₃₂, R₃₃, R₃₄, and R₃₅ are selected independently from the group consisting of hydrogen, alkyl and aryl groups.

17. The OLED device of claim 15 wherein at least one of R₃₁, R₃₂, R₃₃, R₃₄, and R₃₅ is independently selected from the group consisting of halide, alkyl, aryl, alkoxy and aryloxy groups.

18. The OLED device of claim 15 wherein the non-electroluminescent component with the second bandgap is at least 5 vol. percent of the total material in the light emitting layer.

19. The OLED device of claim 15 wherein the non-electroluminescent component with the second bandgap is in the range of 5 to 95 vol. percent of the total material in the light emitting layer.

20. The OLED device of claim 15 wherein the non-electroluminescent component with the second bandgap is in the range of 5 to 75 vol. percent of the total material in the light emitting layer.

21. The device of claim 15 wherein the component of formula (III) is represented by one of the following formulae:

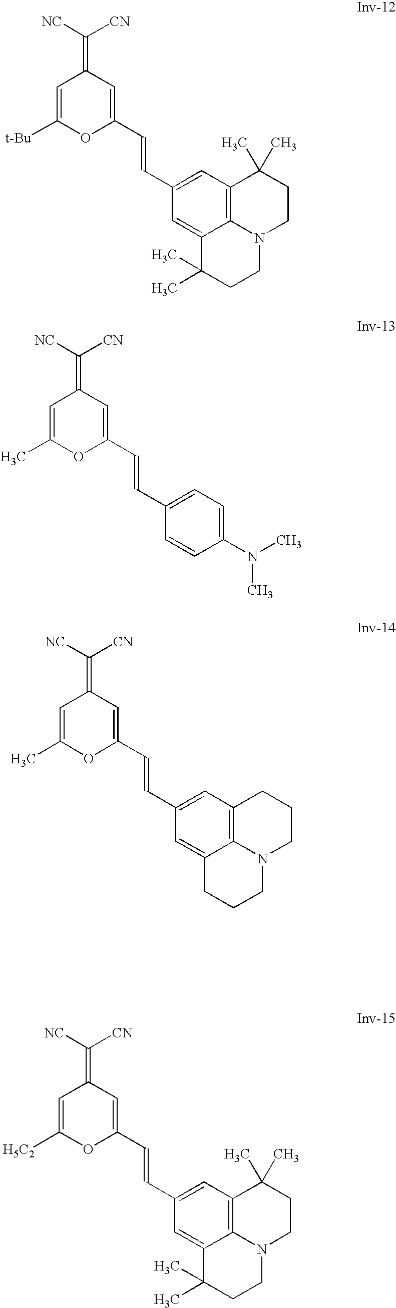

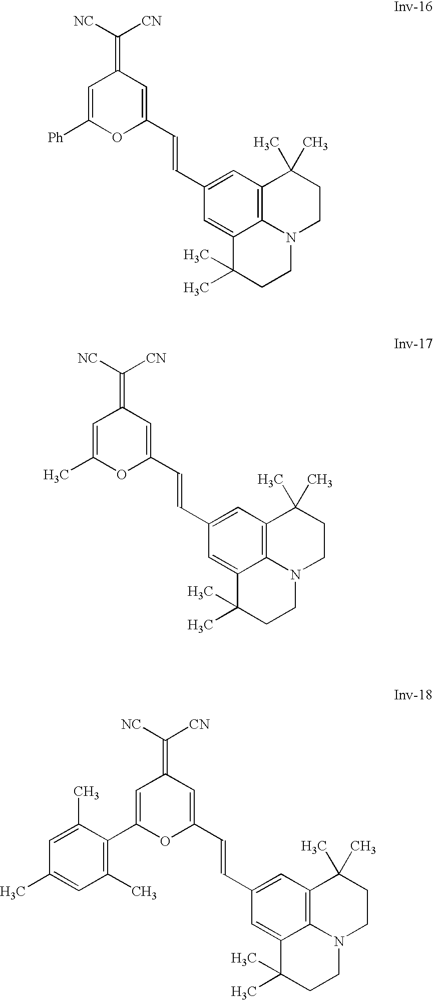

22. The OLED device of claim 19 wherein the electroluminescent component with the first bandgap is in the range from 0.1 to 5 vol. percent of the total material in the light emitting layer.

23. The OLED device of claim 19 wherein the electroluminescent component with the first bandgap is in the range from 0.5 to 1.5 vol. percent of the total material in the light emitting layer.

24. The OLED device of claim 19 wherein the electroluminescent component with the first bandgap is represented by Inv-12:

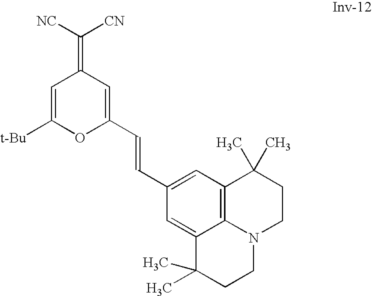

25. The OLED device of claim 7 wherein R₃, R₄, and R₅ are selected from alkyl groups.

26. The OLED device of claim 7 wherein R₃, R₄, and R₅ are methyl groups.

27. The OLED device of claim 1 wherein the non-electroluminescent component with the second bandgap is represented by one of the following formulae;

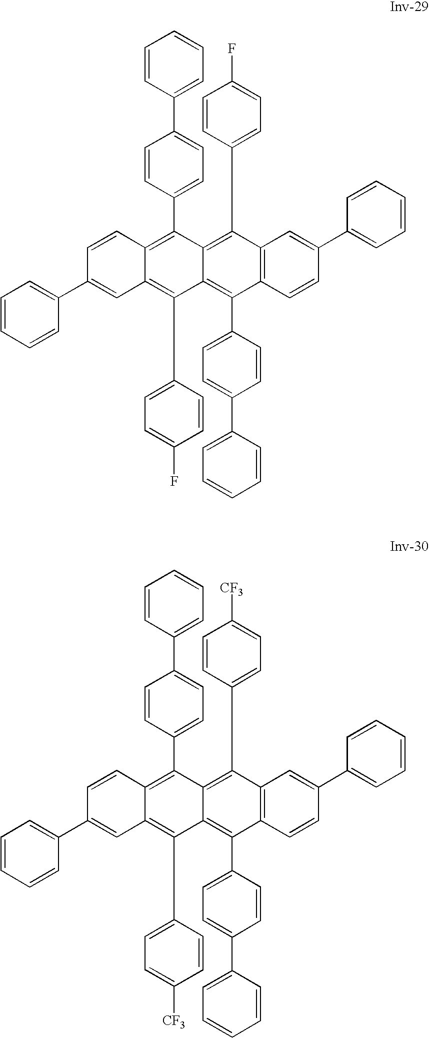

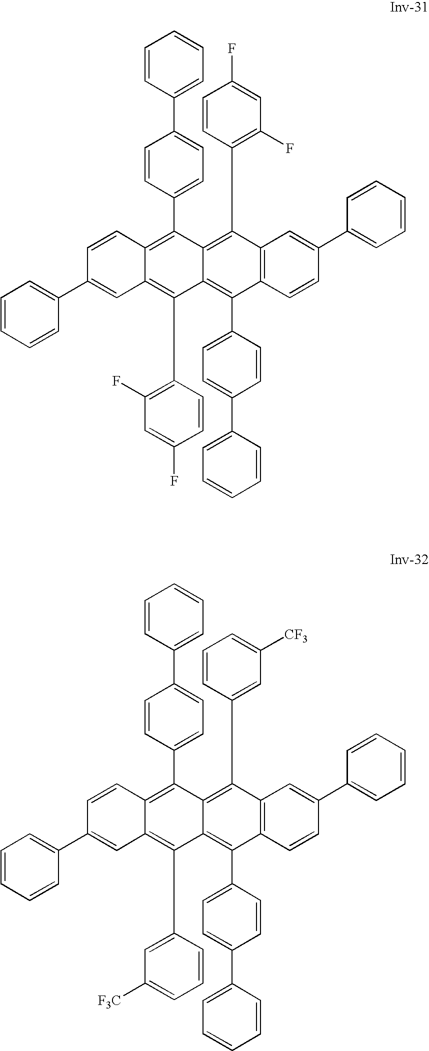

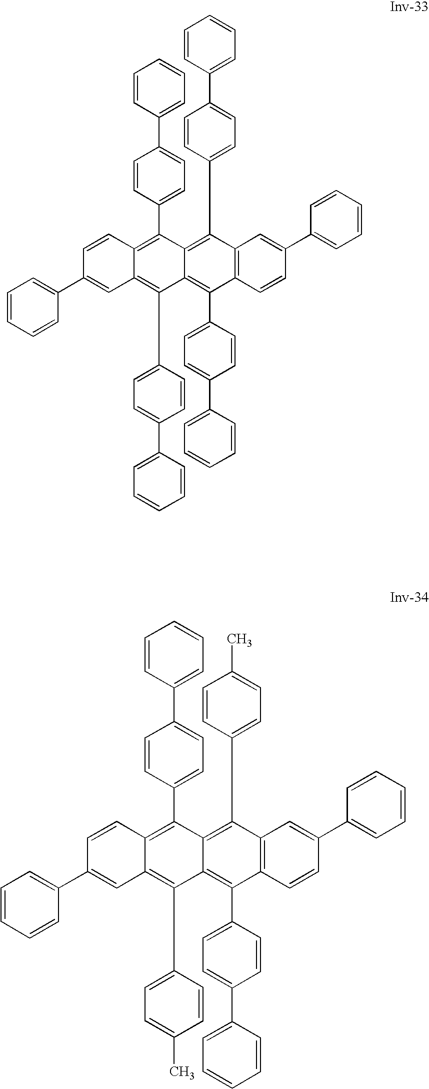

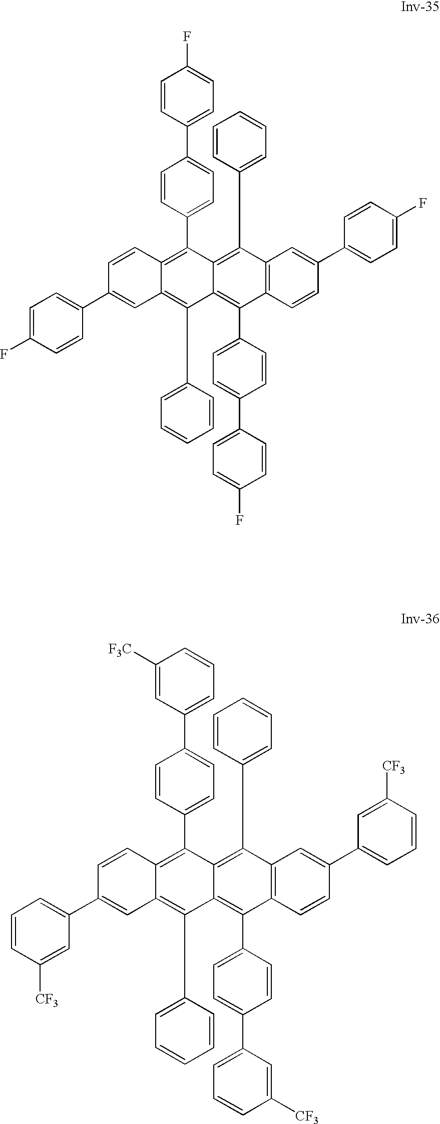

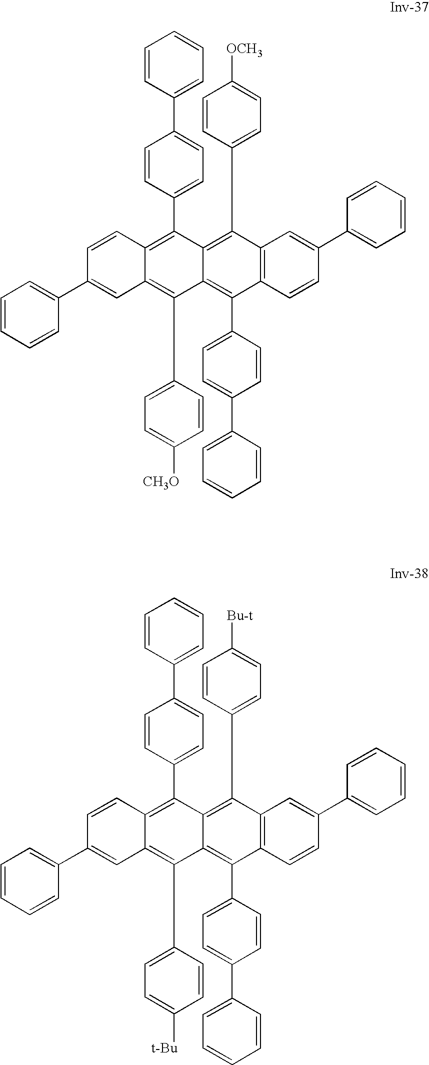

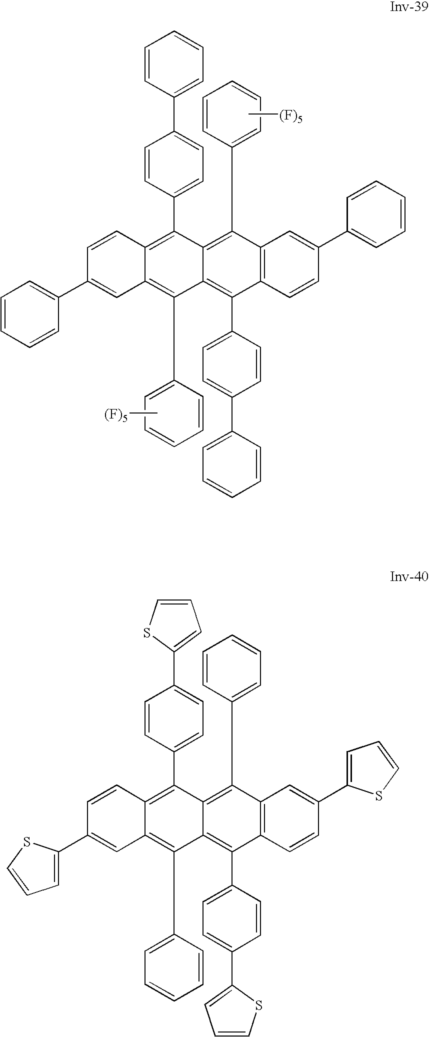

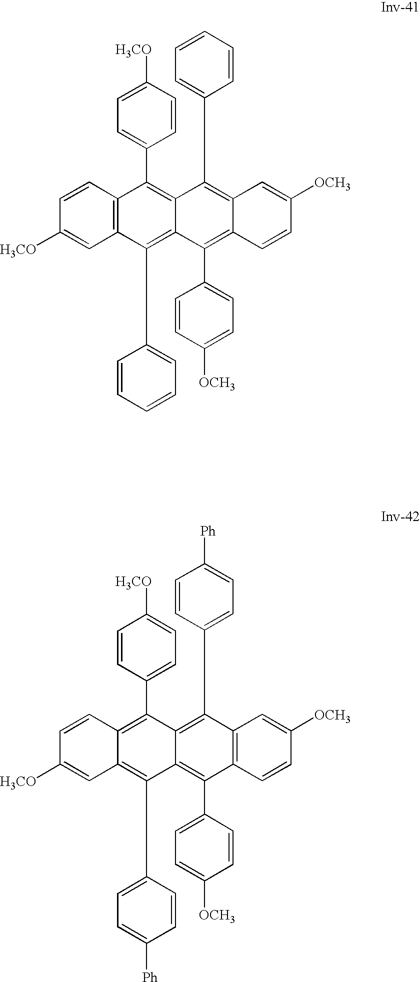

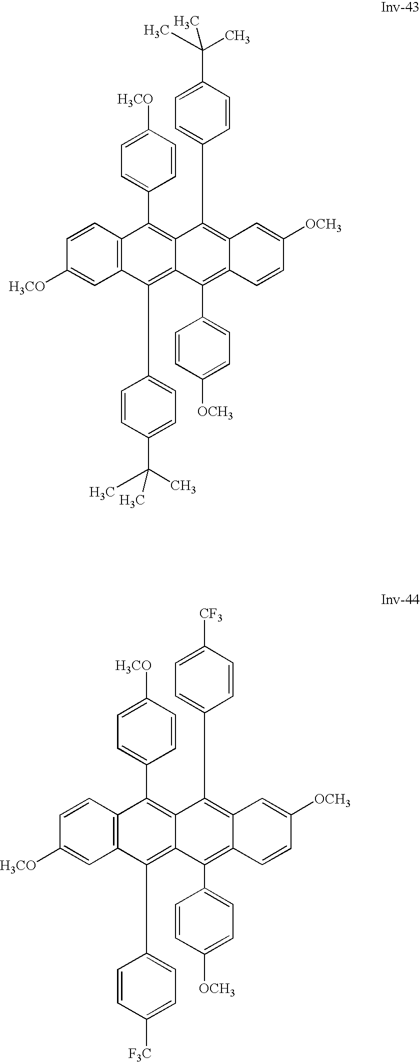

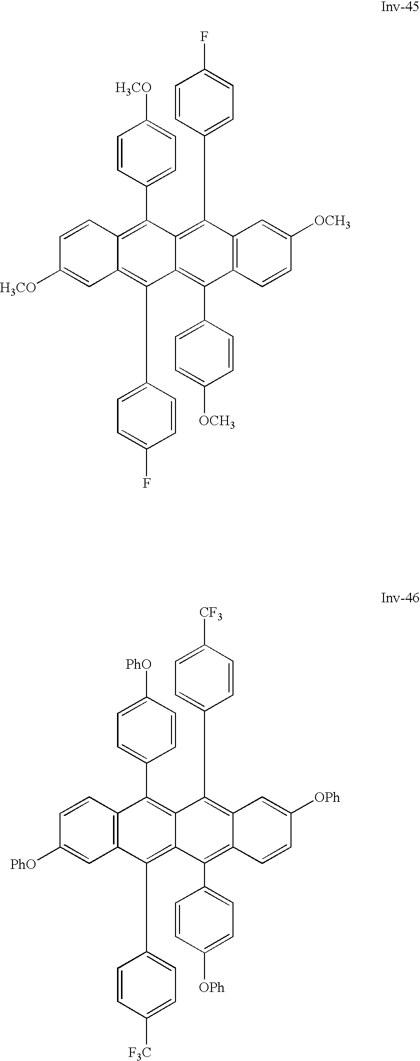

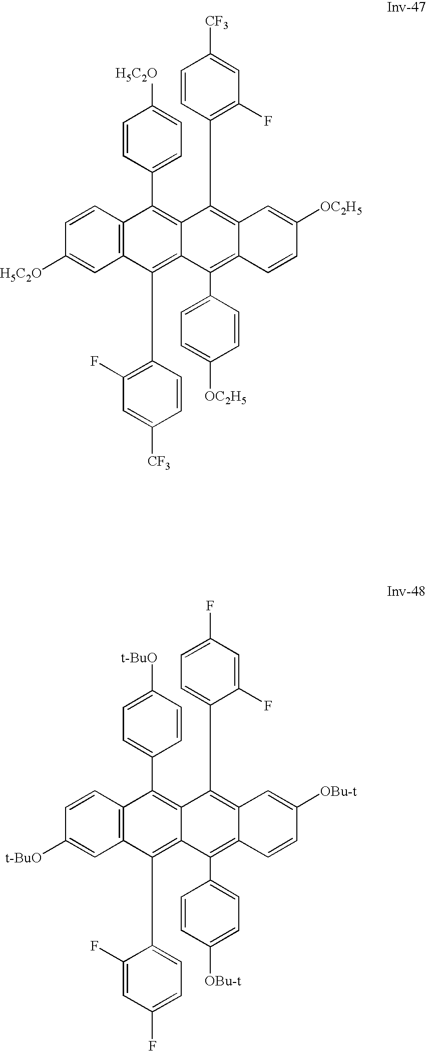

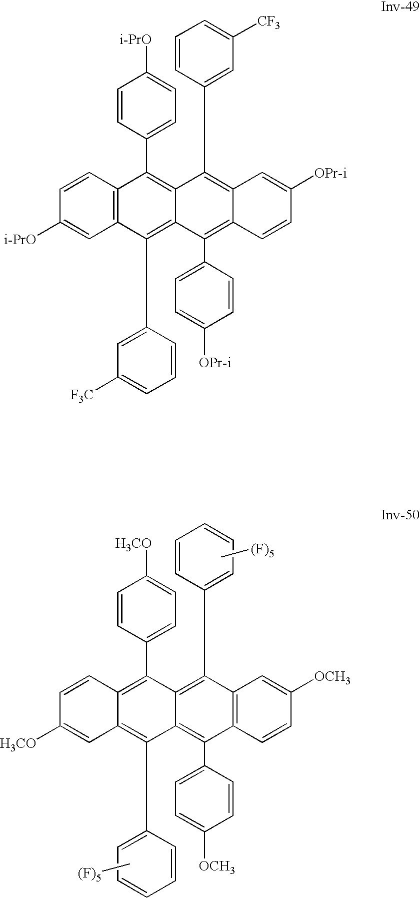

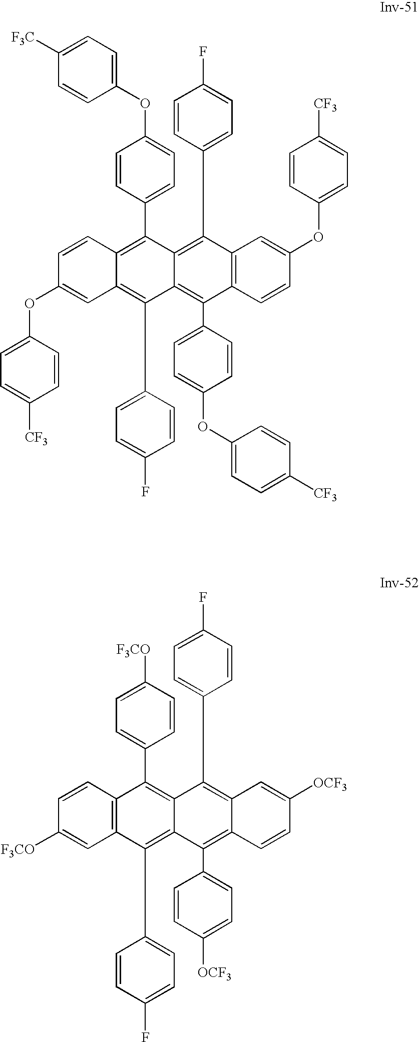

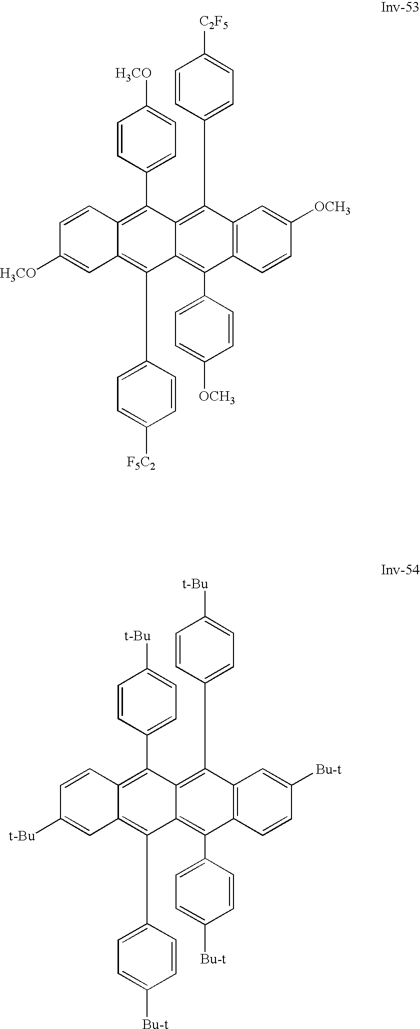

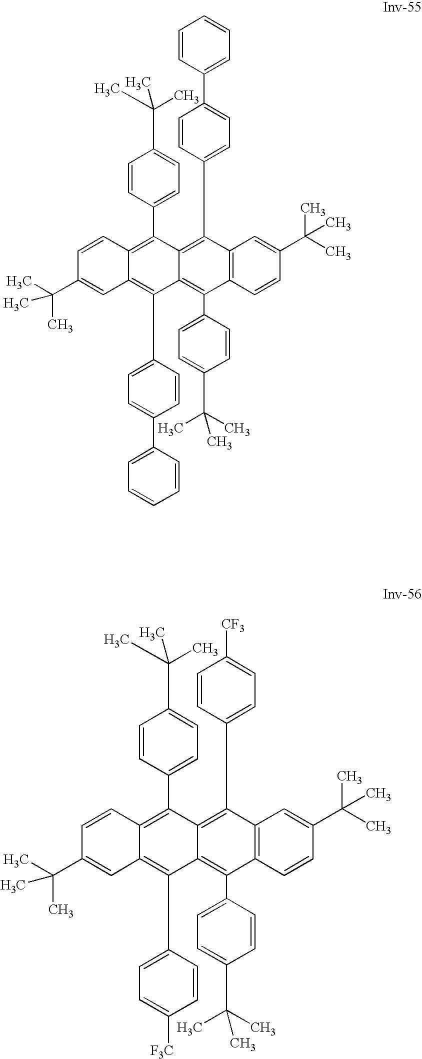

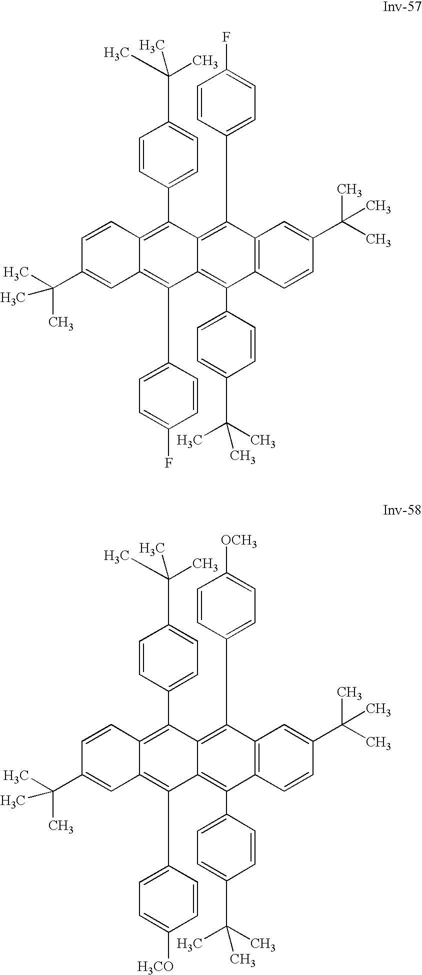

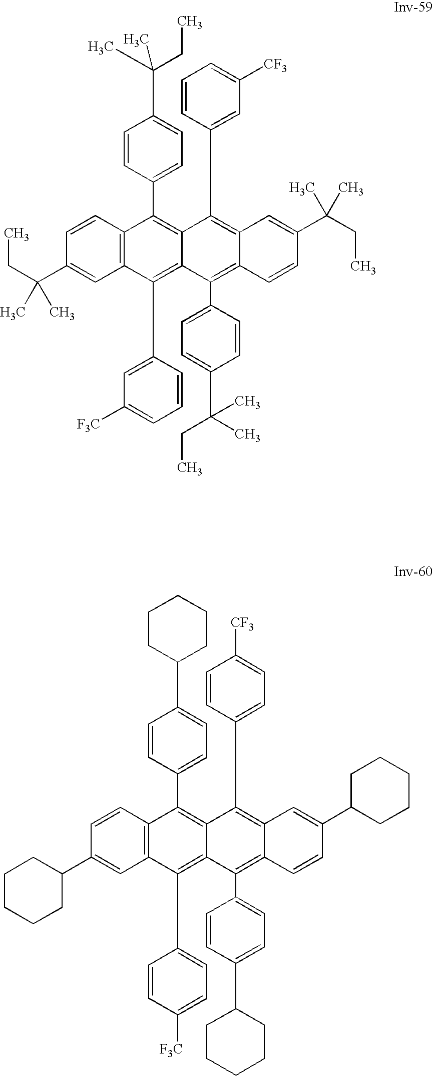

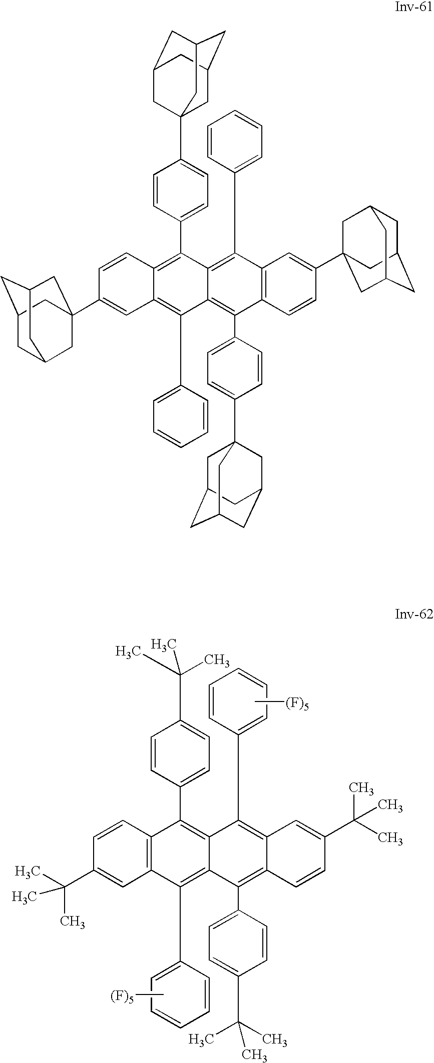

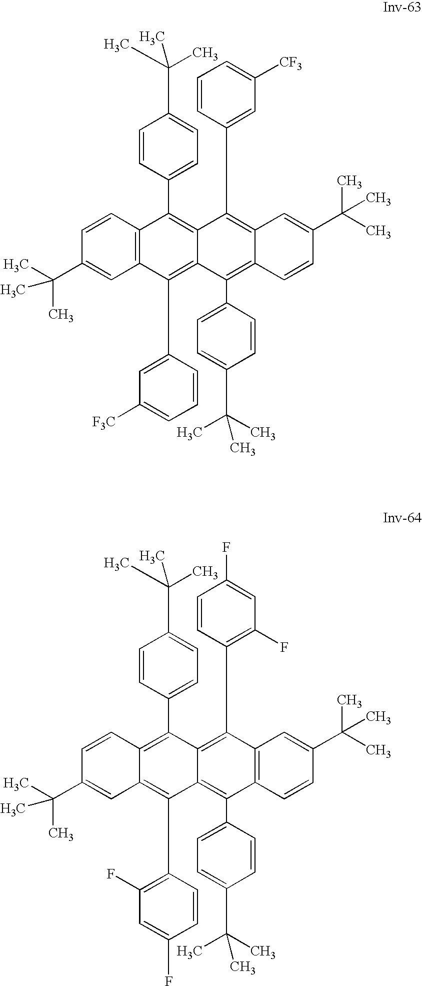

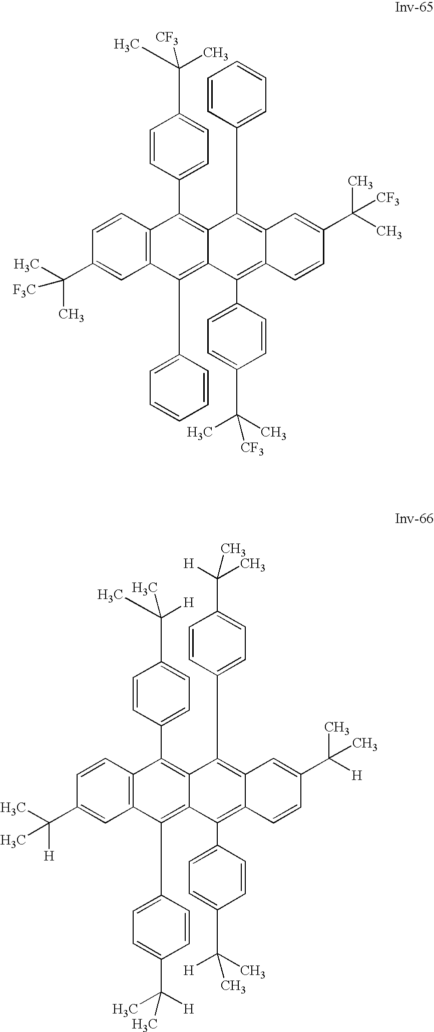

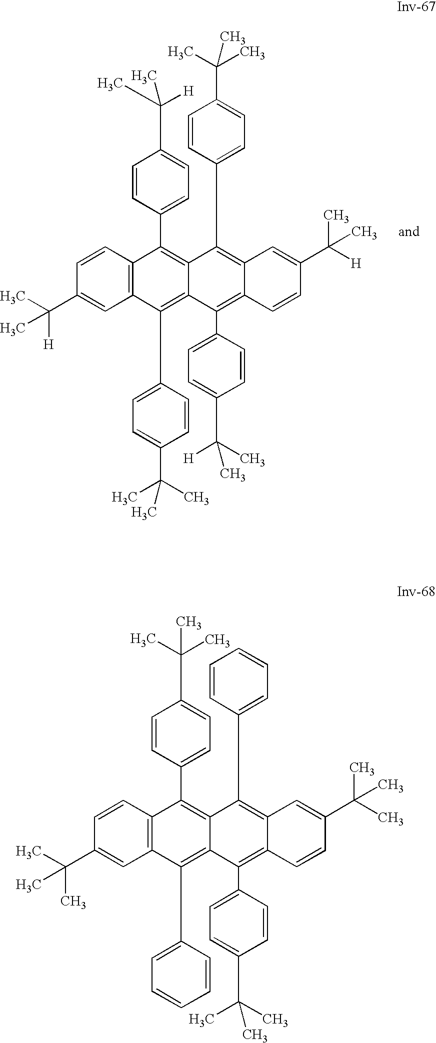

28. The device of claim 1 wherein the one or more non-electroluminescent components with a further bandgap comprises a compound represented by formula (IV): 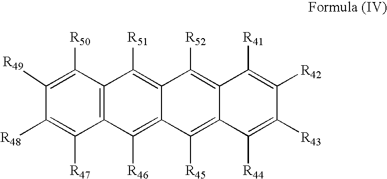
wherein:
R₄₁, R₄₂, R₄₃, R₄₄, R₄₅, R₄₆, R₄₇, R₄₈, R₄₉, R₅₀, R₅₁, and R₅₂ are independently selected as hydrogen or substituents;
provided that any of the indicated substituents may join to form further fused rings.

29. The device of claim 28 wherein at least one of R₄₁, R₄₂, R₄₃, R₄₄, R₄₅, R₄₆, R₄₇, R₄₈, R₄₉, R₅₀, R₅₁, and R₅₂ are independently selected from the group consisting of halide, alkyl, aryl, alkoxy and aryloxy groups.

30. The device of claim 1 wherein the non-electroluminescent component with a further bandgap is selected from the following compounds:

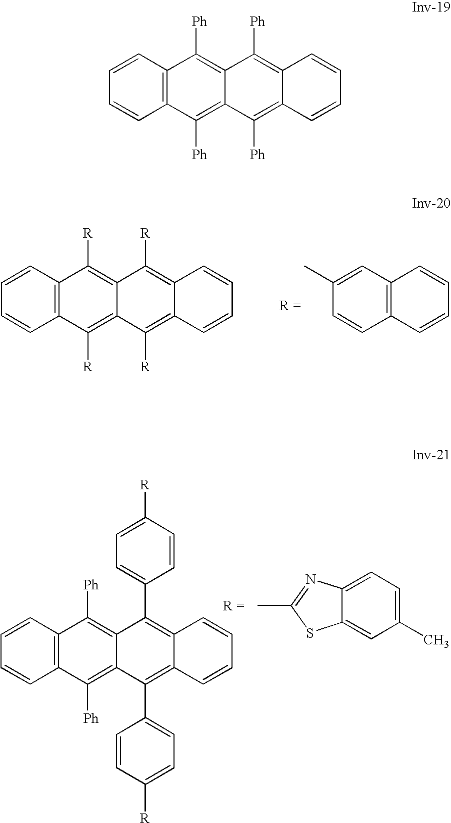

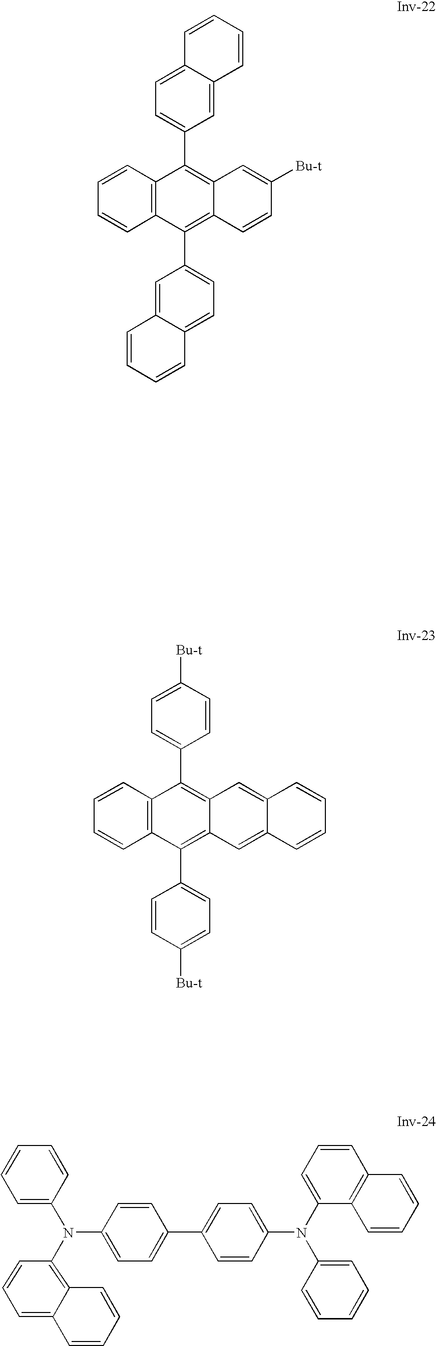

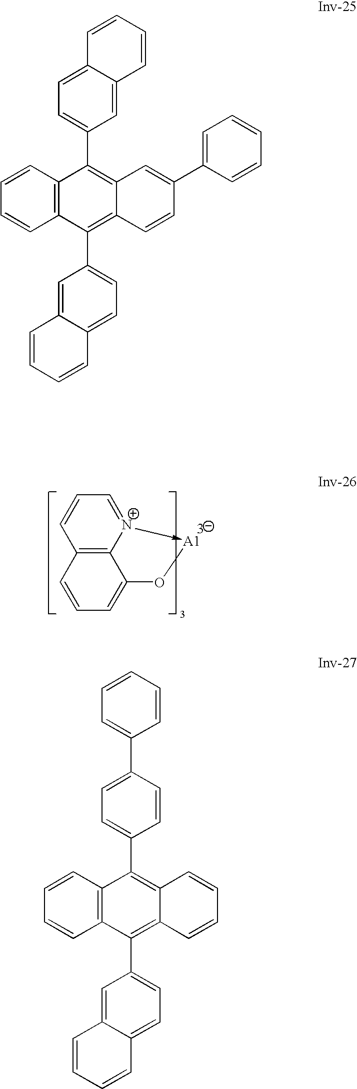

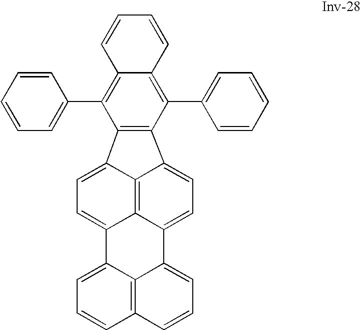

31. The device of claim 1 wherein the one or more non-electroluminescent components with a further bandgap comprises more than one material selected from the following compounds:

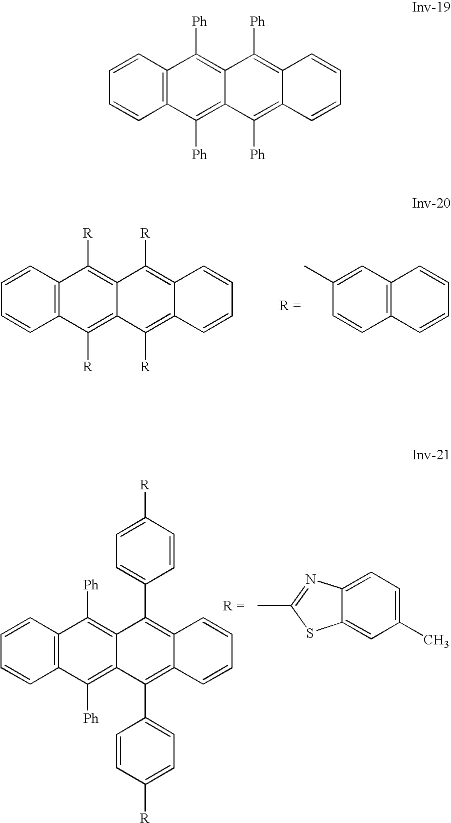

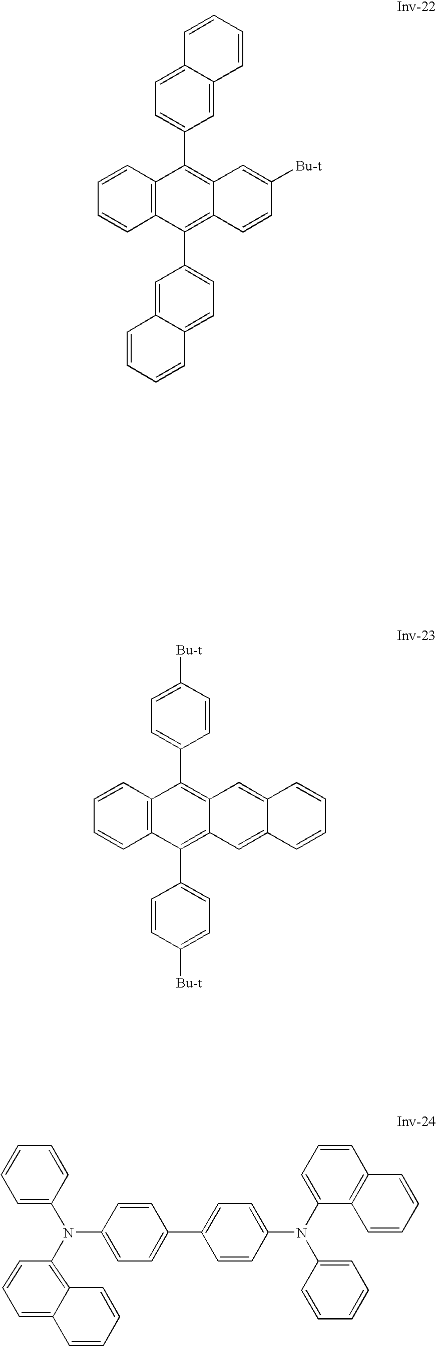

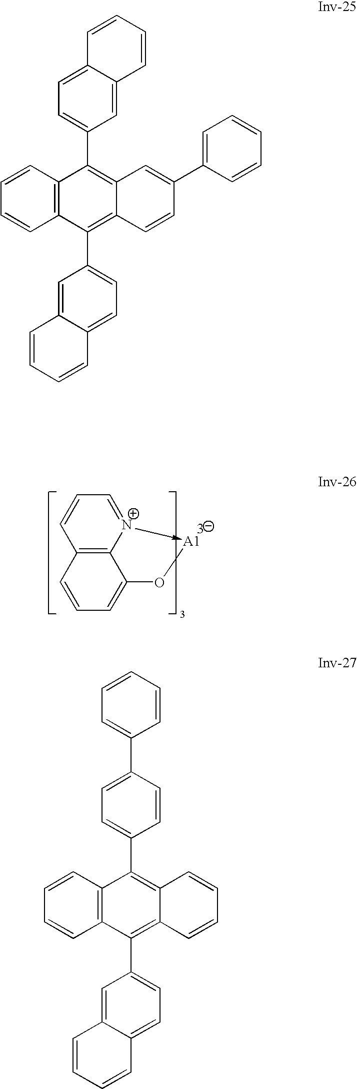

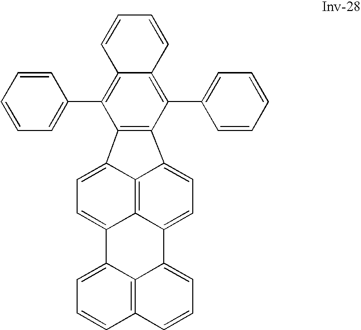

32. An OLED device of claim 1 comprising;
i) a substrate;
ii) an anode disposed over the substrate;
iii) a hole injecting layer disposed over the anode;
iv) a hole transport layer disposed over the hole injecting layer;
v) a light emitting layer as described in claim 1;
vi) an electron transport layer disposed over the light emitting layer; and
vii) a cathode disposed over the electron transport layer.

33. An OLED device of claim 1 wherein
the non-electroluminescent component with the second bandgap is present in an amount of at least 5 vol. percent of the total material in the light emitting layer;
the one or more non-electroluminescent components with further bandgaps are present in a combined amount of 0.1 to 94.9 vol. percent of the total material in the light emitting layer; and
wherein the electroluminescent component is a periflanthene compound.

34. An OLED device of claim 1 wherein, wherein:
the non-electroluminescent component with the second bandgap is present in an amount of 5 to 94.9 vol. percent of the total material in the light emitting layer; and
the one or more non-electroluminescent components with further bandgaps are present in a combined amount of 5 to 94.9 vol. percent of the total material in the light emitting layer and comprise a member selected from the group consisting of tris(8-quinolinolato)aluminum (III) (Alq₃); 2,2′,2″-(1,3,5-benzenetriyl)tris[1-phenyl-1H-benzimidazole] (TPBI); 2-tert-butyl-9,10-bis(2-naphthyl)anthracene (TBADN); 5,6,11,12-tetraphenylnaphthacene (rubrene); N,N′-di-(1-naphthalenyl)-N,N′-diphenyl-4, 4′-diamino(1,1′-biphenyl) (NPB); 4,4′-Bis[N-(1-naphthyl)-N-(2-naphthyl)amino]biphenyl(TNB); 5,12-bis[2-(5-methylbenzothiazolyl)phenyl]-6,11-diphenylnaphthacene (DBZR); 5,12-bis(4-tert-butylphenyl)naphthacene (tBDPN); 5,6,11,12-tetra-(2′-naphthalenyl)naphthacene (NR); 9,10-bis(2-naphthyl)-2-phenylanthracene; and 9-(2-naphthyl)-10-(4-phenyl)phenylanthracene.

35. An OLED device comprising a light emitting layer containing an electroluminescent component having a first bandgap, a non-electroluminescent component having a second bandgap and at least two non-electroluminescent components having further bandgaps, wherein:
i) the second bandgap is equal to or greater than the first bandgap but is not more than 2.7 eV;
ii) each of the further bandgaps are greater than the first and second bandgaps;
iii) the non-electroluminescent component with the second bandgap is present in an amount of 5 to 94.9 vol. percent of the total material in the light emitting layer;
iv) the at least two non-electroluminescent components having further bandgaps are present in a combined amount of 5 to 94.9 vol. percent of the total material in the light emitting layer and at least one is selected from the group consisting of tris(8-quinolinolato)aluminum (III) (Alq₃); 2,2′,2″-(1,3,5-benzenetriyl)tris[1-phenyl-1H-benzimidazole] (TPBI); 2-tert-butyl-9,10-bis(2-naphthyl)anthracene (TBADN); 5,6,11,12-tetraphenylnaphthacene (rubrene); N,N′-di-(1-naphthalenyl)-N,N′-diphenyl-4, 4′-diamino(1,1′-biphenyl) (NPB); 4,4′-Bis[N-(1-naphthyl)-N-(2-naphthyl)amino]biphenyl(TNB); 5,12-bis[2-(5-methylbenzothiazolyl)phenyl]-6,11-diphenylnaphthacene (DBZR); 5,12-bis(4-tert-butylphenyl)naphthacene (tBDPN); 5,6,11,12-tetra-(2′-naphthalenyl)naphthacene (NR); 9,10-bis(2-naphthyl)-2-phenylanthracene; and 9-(2-naphthyl)-10-(4-phenyl)phenylanthracene;
v) the electroluminescent component is present in amount of 0.1 to 5 vol. percent of the total material in the light emitting layer; and
vi) the non-electroluminescent compound with the second bandgap is represented by formula (Ia); 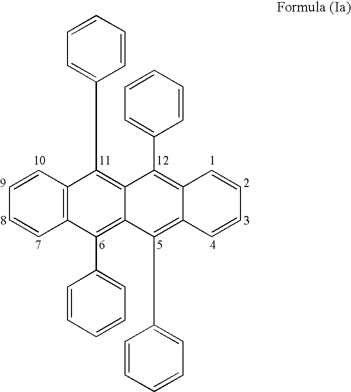
wherein:
a) any hydrogen on the phenyl rings in the 6- and 12-positions can be substituted;
b) there are identical substituent groups at the 2- and 8-positions; and
c) the phenyl rings in the 5- and 11-positions contain only para-substituents identical to the substituent groups in paragraph b).

36. A process for emitting light from the device of claim 1 comprising applying a potential to the device.

37. A process for emitting light from the device of claim 34 comprising applying a potential to the device.
